(19) United States
(12) Patent Application Publication
(10) Pub. No.: US 2026/0056271 A1
(43) Pub. Date: Feb. 26, 2026

(54) METHODS AND SYSTEMS FOR DETERMINING A SPECIFIC ABSORPTION RATE

(71) Applicant: SHANGHAI UNITED IMAGING HEALTHCARE CO., LTD., Shanghai (CN)

(72) Inventor: Rongxing ZHANG, Shanghai (CN)

(73) Assignee: SHANGHAI UNITED IMAGING HEALTHCARE CO., LTD., Shanghai (CN)

(21) Appl. No.: 19/309,587

(22) Filed: Aug. 25, 2025

(30) Foreign Application Priority Data
Aug. 23, 2024 (CN) 202411170268.X
Sep. 30, 2024 (CN) 202411395075.4

(51) Int. Cl. G01R 33/28; G01R 33/54

(52) U.S. Cl. CPC G01R 33/288; G01R 33/543

(57) ABSTRACT

A method for determining a specific absorption rate (SAR) is provided. The method includes a scanning information of a target object; obtaining a target set matching the scanning information of the target object; and determining an SAR estimated value for the target object based on a target RF shimming field parameter of an RF coil and the target set.

### CROSS REFERENCE TO RELATED APPLICATIONS

This application claims priority to Chinese Patent Application No. 202411395075.4, filed on Sep. 30, 2024, and Chinese Patent Application No. 202411170268.X, filed on Aug. 23, 2024, the entire contents of each of which are incorporated herein by reference.

### TECHNICAL FIELD

The present disclosure relates to the field of magnetic resonance (MR) technology, and in particular to a method for determining a specific absorption rate.

### BACKGROUND

In a field of magnetic resonance imaging (MRI) technology, a traditional method for evaluating a specific absorption rate (SAR) suffers from a low efficiency. The method typically requires, for each preset radiofrequency (RF) shimming field parameter, a lookup table including a sensitivity distribution matrix corresponding to each position point in a simulation object. Due to complexity of an internal structure of a human body and inhomogeneity of an RF field inside the human body, this method needs to deal with a great count of data points, which results in a high consumption of computational resources and a low computational efficiency. In addition, as a magnetic field strength increases, the inhomogeneity of the RF (B1) field intensifies and the limited RF shimming field parameters cannot satisfy a clinical scanning requirement, which requires real-time RF field optimizations for different target objects, which increases complexity for SAR determination. Thus, the traditional method for SAR estimation suffers from a great amount of computation, low computational efficiency, and difficulty in adapting to requirements of different target objects and scanning portions when determining the SAR.

There is therefore an urgent need for a method for determining the SAR, which can more efficiently and accurately determine the SAR and estimate the SAR to adapt to different scanning conditions and target object needs.

### SUMMARY

One or more embodiments of the present disclosure provide a method for determining a specific absorption rate (SAR). The method includes: obtaining scanning information of a target object, the scanning information including a physiological feature of the target object and position information of a radiofrequency (RF) coil in a magnetic resonance (MR) device; obtaining a target set matching the scanning information of the target object, the target set including a plurality of target sensitivity distribution matrices corresponding to a first count of target local hotspots, the first count of target local hotspots being selected from a second count of initial local hotspots on a body model, and the second count being greater than the first count; and determining an SAR estimated value for the target object based on an RF shimming field parameter of the RF coil and the target set.

### BRIEF DESCRIPTION OF THE DRAWINGS

The present disclosure will be further illustrated by way of exemplary embodiments, which is described in detail by means of the accompanying drawings. These embodiments are not limiting, and in these embodiments, the same numbering denotes the same structure, wherein:

FIG. 1 is a schematic diagram illustrating an exemplary application scenario for determining a specific absorption rate (SAR) and a method for SAR estimation applied to magnetic resonance (MR) scanning according to some embodiments of the present disclosure;

FIG. 2 is a schematic diagram illustrating an exemplary structure of an electronic device according to some embodiments of the present disclosure;

FIG. 3 is a block diagram illustrating a plurality of exemplary radio frequency (RF) coils of a magnetic resonance device according to some embodiments of the present disclosure;

FIG. 4 is a block diagram illustrating an exemplary system for determining an SAR according to some embodiments of the present disclosure;

FIG. 5 is a flowchart illustrating an exemplary method for determining an SAR according to some embodiments of the present disclosure;

FIG. 6 is a schematic diagram illustrating exemplary estimation effects of two SAR estimated values according to some embodiments of the present disclosure;

FIG. 7 is a schematic diagram illustrating an exemplary process for determining an SAR estimated value according to some embodiments of the present disclosure;

FIG. 8 is a schematic diagram illustrating an exemplary process for SAR estimation applied to MR scanning according to some embodiments of the present disclosure;

FIG. 9 is a schematic diagram illustrating an exemplary control process for MR scanning according to some embodiments of the present disclosure;

FIG. 10 is a flowchart illustrating an exemplary method for determining an SAR according to another embodiment of the present disclosure;

FIG. 11 is a schematic diagram illustrating an exemplary method for determining an SAR of a target object according to some embodiments of the present disclosure;

FIG. 12 is a flowchart illustrating an exemplary method for determining an SAR according to another embodiment of the present disclosure; and

FIG. 13 is a flowchart illustrating an exemplary method for determining an SAR according to another embodiment of the present disclosure.

### DETAILED DESCRIPTION

To more clearly illustrate the technical solutions of the embodiments of the present disclosure, the accompanying drawings required to be used in the description of the embodiments will be briefly described below. Obviously, the accompanying drawings in the following description are only some examples or embodiments of the present disclosure, and it is possible for those skilled in the art to apply the present disclosure to other similar scenarios in accordance with these drawings without creative labor. Unless obviously obtained from the context or the context illustrates otherwise, the same numeral in the drawings refers to the same structure or operation.

It should be understood that, as used herein, the terms “system,” “device,” “unit,” and/or “module” as used herein is a way to distinguish between different components, elements, parts, sections, or assemblies at different levels. However, the words may be replaced by other expressions if other words accomplish the same purpose.

As of the present disclosure and the claims, unless the context clearly suggests an exception, “a,” “an,” “one,” and/or “the” do not refer specifically to the singular, but may also include the plural. Generally, the terms “including” and “comprising” suggest only the inclusion of clearly identified operations and elements. In general, the terms “including” and “comprising” only suggest the inclusion of explicitly identified operations and elements that do not constitute an exclusive list, and the method or device may also include other operations or elements.

Flowcharts are used in the present disclosure to illustrate operations performed by a system according to embodiments of the present disclosure. It should be appreciated that the preceding or following operations are not necessarily performed in an exact sequence. Instead, operations may be processed in reverse order or simultaneously. Also, it is possible to add other operations to these processes, or to remove an operation or operations from these processes.

In the present disclosure, the terms “coil channel,” “RF coil channel,” “RF channel,” and “transmission channel,” can be used interchangeably.

Currently, a magnetic resonance (MR) device typically includes a magnet that generates a static field (B0), a gradient system that generates a gradient field for spatial encoding, a radiofrequency (RF) transmission system (e.g., including an RF coil) that generates an RF field, a receiving system (e.g., including a receiving coil for imaging use) that receives MR signals, and associated MR peripherals (e.g., including a scanning bed, a human-computer interaction device, an electronic cabinet, a computer device, etc.).

To pursue a higher imaging signal-to-noise ratio (SNR), a magnetic field strength of the static field is improved, and as the magnetic field strength of the static field is increased, a frequency of the RF field is also increased, and due to a presence of a dielectric effect, homogeneity of the RF field inside a human body decreases as the field strength increases. To solve the above problem, a multi-channel emission technology may be used to mitigate the problem of uneven RF field in ultra-high-field RF emission by adjusting a combination of an emission amplitude and a phase of each RF channel.

As the amplitude and the phase of each emission channel need to be determined based on pre-scanning of a specific scanning target object, emission magnitude ratios and phase differences between different channels may vary greatly. For the same RF channel, different target objects and different scanning portions may have different emission amplitude ratios and phase differences. The emission amplitude ratio and the phase difference between the channels are the RF shimming field parameter.

In a specific absorption rate (SAR) management, a forward power and a reverse power of the RF emission may be monitored and a total absorption power is determined based on the forward power and the reverse power. The total absorption power includes three parts, one portion of which is lost by the RF coil itself, for example, electronics and conductors of the RF coil and structural components of the RF coil are converted to thermal energy by heat generation; another portion is radiated to a surrounding space, resulting in a radiation loss, and the other portion is absorbed by the scanned target object. As the RF field is uneven in the interior of the target object, a proportion absorbed by each body portion of the target object is inconsistent, and different RF shimming field parameters change a distribution of the RF field, which also affects a proportion of the absorbed power of the target object in the total absorption power. Therefore, different RF shimming field parameters pose a great challenge for MRI SAR management.

Currently, as the forward power and the reverse power are measured by a directional coupler and a data acquisition link in a multi-channel transmission system, and a proportion of the absorbed power of the human body to the total absorption power when using preset RF shimming field parameters may be pre-measured or calculated, a proportion of the absorbed power in each portion of the human body may be simulated in advance. At a field strength of 3T and below, the RF field inhomogeneity is not obvious, and thus a preset finite count of RF shimming field parameters may be used to predefine the same scanning portion of different objects, and a lookup table may be established by traversing through the finite count of RF shimming field parameters. The lookup table includes, for each RF shimming field parameter, a sensitivity distribution matrix corresponding to each position point in a simulation object, and then, during actually scanning, the SAR calculation and monitoring may be performed based on the selected RF shimming field parameters and the lookup table, to improve a safety. It should be noted that the simulation object refers to a virtual model constructed by modeling, for example, a virtual body model or an organ model constructed by computer modeling. The target object refers to a detection object or a living body that is actually detected and scanned.

On the one hand, when establishing the lookup table in a related technology, for each preset RF shimming field parameter, each position point in the simulation object is required for calculating and storing the corresponding sensitivity distribution matrix, and the SAR of each position point is calculated based on the position point and the corresponding sensitivity distribution matrix, and an SAR estimated value under the RF shimming field parameter is determined from the SAR of the position point. A count of the position points is usually in an order of millions, that is, for each RF shimming field parameter, it is necessary to calculate the specific absorption rates (SARs) of millions of position points to find the SAR estimated value under the RF shimming field parameter. Therefore, the current manner requires a great computational resources and has a low computational efficiency. On the other hand, with an increase of the static field, the inhomogeneity of the RF field is intensified, and a limited RF shimming field parameter may not satisfy requirements of clinical scanning, which requires real-time RF field optimizations for different target objects. Considering that the amplitude ratio and the phase difference of each channel emission may have arbitrary combinations, and information of all RF shimming field parameters cannot be obtained when establishing the lookup table, this brings more challenges to the determination of the SAR. Based on this, a method for SAR estimation applied to MR scanning is required, which is described below.

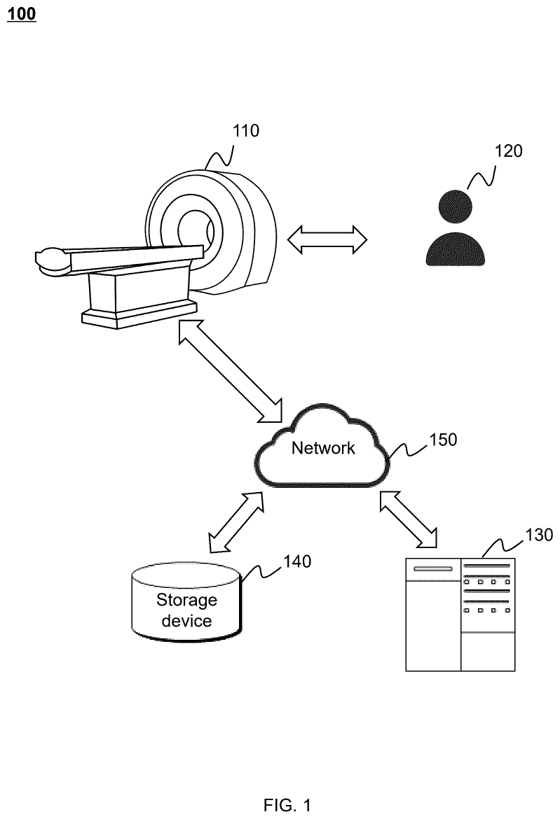

FIG. 1 is a schematic diagram illustrating an exemplary application scenario for determining an SAR and a method for SAR estimation applied to MR scanning according to some embodiments of the present disclosure. The method for determining the SAR provided by embodiments of the present disclosure may be applied in an application environment 100 as shown in FIG. 1.

In some embodiments, as shown in FIG. 1, the application scenario 100 of the method for SAR estimation applied to the MR scanning (hereinafter referred to as the application scenario) includes an MR device 110, a target object 120, a processor 130, a storage device 140, and a network 150.

In some embodiments, one or more components of the application scenario 100 transmit data to other components of the application scenario 100 via the network 150. For example, the processor 130 obtains information and/or data related to the target object 120 in the MR device 110 and the storage device 140 via the network 150, or sends the information and/or data to the MR device 110 and the storage device 140.

The MR device 110 may be configured to perform the MR scanning of the target object 120. In some embodiments, the target object is biological or non-biological. For example, the target object includes a human body, an artificial object, etc. In some embodiments, the scanning object includes a specific portion of the body, e.g., a head, a neck, a chest, etc. or any combination thereof. In some embodiments, the scanning object includes a specific organ, e.g., a liver, a kidney, a pancreas, a bladder, a uterus, a rectum, etc. or any combination thereof. In some embodiments, the scanning object includes a region of interest (ROI), e.g., a tumor, a nodule, etc.

In some embodiments, the MR device 110 obtains a great amount of original, unprocessed data by performing an MR scanning of the target object 120. The original data may also be referred to as raw data. In some embodiments, the MR device 110 performs the MR scanning on the target object 120 according to a certain scanning sequence. The scanning sequence includes, but is not limited to, a free induction decay (FID) sequence, a self-selected echo (SE) sequences, a gradient echo (GRE) sequence, a heterogeneous sequences (HS), etc. In some embodiments, the MR device 110 performs the scanning using different scanning sequences for different target objects 120. For example, the MR device 110 employs an Ax SE T1 scanning sequence for a conventional head and a Cor SE T1 scanning sequence for a pituitary gland. In some embodiments, the MR device 110 includes a 1.5T MR device, a 3T MR device, a 5T MR device, a 7T MR device, etc.

In some embodiments, the MR device 110 sends an MR signal via the network 150 to the processor 130 for processing. In some embodiments, the MR device 110 detects relevant data or instructions from the processor 130 to perform the MR scanning.

The foregoing description of the MR device 110 is for illustrative purposes only and is not intended to limit the scope of the present disclosure.

The processor 130 may be used to process data from one or more components in application scenario 100 or from an external data source. For example, the processor 130 is configured to receive data and information from the MR device 110. As another example, the processor 130 is configured to send control instructions (e.g., a power on instruction, a power off instruction, a warm up instruction, etc.) to the MR device 110.

In some embodiments, the processor 130 is a single server or a server group. The server group may be centralized or distributed. In some embodiments, the processor 130 is local or remote. In some embodiments, the processor 130 includes a central processing unit (CPU), an application-specific integrated circuit (ASIC), an application-specific instruction set computer device (ASIP), an image processing unit (GPU), a physical operations processing unit (PPU), a digital signal computer device (DSP), a computer device, a microcomputer device unit, a reduced instruction set computer (RISC), a microcomputer device, etc., or any combination thereof. In some embodiments, the processor 130 is local or remote. In some embodiments, the processor 130 is integrated in an operator console of the imaging device 110. In some embodiments, the processor 130 is implemented on a cloud platform. Merely by way of example, the cloud platform includes a private cloud, a public cloud, a hybrid cloud, a community cloud, a distributed cloud, an internal cloud, a multi-tiered cloud, etc., or any combination thereof.

The storage device 140 is configured to store data, instructions, and/or any other information. In some embodiments, the storage device 140 stores data and/or information (e.g., an MRI image, an RF coil port parameter, etc.) sent or acquired by the MR device 110 and the processor 130. In some embodiments, the storage device 140 stores data and/or instructions used by the processor 130 to perform or use to accomplish the exemplary method described in the present disclosure. In some embodiments, the storage device 140 includes a mass storage, a removable memory, etc., or any combination thereof. In some embodiments, the storage device 140 is integrated into the processor 130.

The network 150 may be any suitable network capable of facilitating an exchange of the information and/or data. In some embodiments, the network 150 is any one or more of a wired network or a wireless network. The network 150 may include one or more network access points. Through the one or more network access points, one or more of the components of the application scenario 100 may connect to the network 150 to exchange the data and/or information. In some embodiments, the network 150 is any one or more of a wired network or a wireless network. In some embodiments, the network 150 is a variety of topology structures such as peer-to-peer, shared, centralized, or a combination of the topology structures.

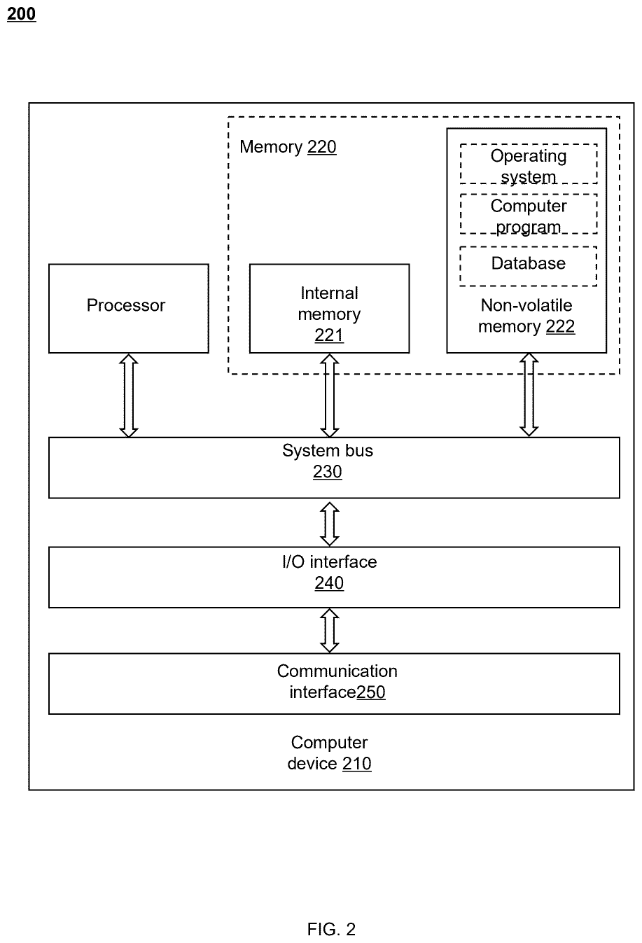

More contents on each of the above components may be found in FIGS. 2-13 and their related descriptions.

It should be noted that the application scenario 100 for a method for SAR estimation applied to the MR scanning is provided for illustrative purposes only, and is not intended to limit the scope of the present disclosure. For those skilled in the art, a variety of modifications or variations may be made in accordance with the description of the present disclosure. However, the variations and modifications do not depart from the scope of the present disclosure.

FIG. 2 is a schematic diagram illustrating an exemplary structure of an electronic device according to some embodiments of the present disclosure. The method for determining an SAR provided by the embodiments of the present disclosure may be applied in an electronic device 200 as shown in FIG. 2.

In some embodiments, as shown in FIG. 2, the electronic device 200 includes a computer device 210, a memory 220, an internal memory 221, a non-volatile memory 222, a system bus 230, an input/output (I/O) interface 240, and a communication interface 250. In some embodiments, the computer device 210, the memory 220, the internal memory 221, the non-volatile memory 222, the system bus 230, the I/O interface 240, and the communication interface 250 are communicatively connected. The non-volatile memory 222 is installed with an operating system, a computer program, and a database.

The computer device 210 may be configured to enable an interaction between a user and an MR device. The computer device 210 may include a server, a personal computer, a laptop computer, a smartphone, a tablet computer, a smart cell phone, etc., or any combination thereof. The computer device 210 may include a processor, a memory, and a network interface connected via the system bus 230 or connected wirelessly. The processor of the computer device is configured to provide computing and control capabilities. The network interface is configured to communicate with an external terminal via a network connection.

In some embodiments, the computer device 210 interacts with other components (e.g., the memory 220, etc.) in the electronic device 200 via the network 150. For example, the computer device 210 obtains a physiological feature, etc. of the target object from the memory 220 via the network 150. The foregoing examples are intended only to illustrate a breadth of a device range of the computer device 210 and are not a limitation of a scope thereof.

The memory 220 refers to a device for storing the data, the instructions, and/or any other information.

In some embodiments, the memory 220 includes the internal memory 221 and the non-volatile memory 222.

In some embodiments, the memory 220 is similar to the storage device 140. More contents about the storage device 140 may be found in FIG. 1 and the related descriptions.

The internal memory 221 provides an environment for operating of the operating system and the computer program in the non-volatile memory. The computer program may be used to implement the method for determining the SAR.

The non-volatile memory 222 stores the operating system, the computer program, and the database. The database of the computer device is configured to store data in a process of determining the SAR.

The system bus 230 refers to a communication channel used in the electronic device to connect the various components.

In some embodiments, the system bus 230 is configured for data transmission.

The I/O interface 240 refers to an interface in the electronic device 200 for connecting the computer device 210 to an external device (e.g., a keyboard, a mouse, a monitor, a hard disk, etc.).

In some embodiments, the I/O interface 240 is configured for transmitting the data and receiving a control signal to the external device.

The communication interface 250 refers to an interface that is configured to enable communications between components. For example, the communication interface 250 includes a broadband interface, a wireless network interface, etc.

The computer device, the memory 220, and the I/O interface 240 are connected via the system bus 230, and the communication interface 250 is connected to the system bus 230 via the I/O interface 240. The computer device 210 is configured to provide the computing and control capabilities. The memory 220 of the computer device 210 includes the non-volatile memory 222 and the internal memory 221. The non-volatile memory 222 stores the operating system, the computer program, and the database. The internal memory 221 provides an environment for the operating of the operating system and the computer program in the non-volatile memory 222. The database of the computer device 210 is configured to store relevant data. The I/O interface 240 of the computer device 210 is configured to enable the exchange of information between the computer device and the external device. The communication interface 250 of the computer device 210 is configured to communicate with an external terminal via the network connection. When the computer program is performed by the computer device, the method for SAR estimation applied to the MR scanning is implemented.

It is appreciated by those skilled in the art that the structure illustrated in FIG. 2 is only a block diagram of a portion of the structure related to the solution of the present disclosure, and does not constitute a limitation on the computer device to which the solution of the present application is applied. The specific computer device may include more or fewer components than shown in the drawings, or combine certain components, or have a different arrangement of the components.

This embodiment is illustrated by way of example with the method being applied to a server, and it will be appreciated that the method may also be applied to a terminal, and may also be applied to a system that includes a terminal and a server, and is realized through the interaction of the terminal and the server. The terminal may be, but is not limited to, a variety of personal computers, laptop computers, smartphones, and tablets. The server may be implemented with a stand-alone server or a cluster of servers including a plurality of servers. It should be noted that this method is applicable to a high-field magnetic resonance system with a field strength of 3T, an ultra-high-field magnetic resonance system with field strengths of 4.7, 5T, 7T, etc.

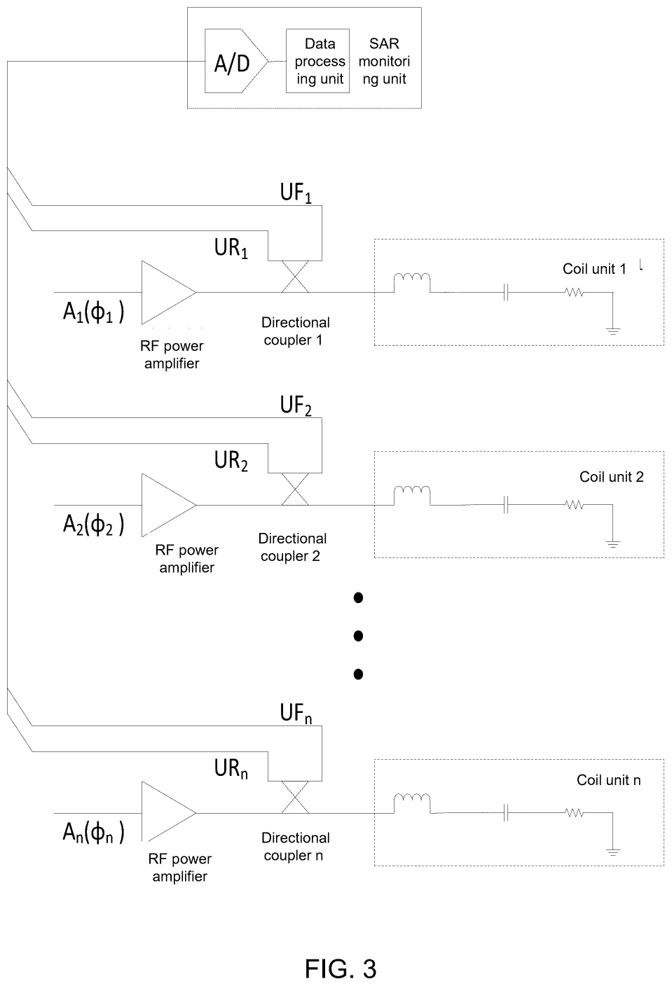

To more clearly introduce the embodiments of the present disclosure, the embodiments are described herein in conjunction with FIG. 3. FIG. 3 is a block diagram illustrating a plurality of exemplary RF coils of an MR device according to some embodiments of the present disclosure. In a multi-channel transmission system of the MR device shown in FIG. 3, an RF transmission signal Aₙ(φₙ) of each channel is first amplified by an RF power amplifier, then collected by a directional coupler for collecting a forward voltage UFₙ and a reverse voltage URₙ, respectively, and the RF transmission signal Aₙ(φₙ) is finally fed into an RF coil for an excitation of the MR signal. The collected signals are converted to digital signals by an analog-to-digital conversion (ADC) unit, pass through a data processing unit, and are used by a computer device to perform SAR calculation and management.

The multi-channel transmission system provides the ultra-high-field MR system with more freely adjustable variables, i.e., a transmission complex signal of each RF channel (also referred to as the RF transmission signal), A₁(φ₁), A₂(φ₂), . . . Aₙ(φₙ), controls the RF field of the coil unit of the RF channel to be combined into a more even synthesized RF field in a target imaging region, where A₁, A₂, . . . , An respectively denote an amplitude of the transmission signal of an RF channel, and φ₁, φ₂, . . . , φₙ each denote a phase of the transmission signal of a transmission channel (RF channel).

The RF signal of each RF channel may be calibrated by an RF shimming field parameter for a currently scanned target object. The RF shimming field parameter is a combined form of the RF signals, including emission magnitude ratios and phase differences of the RF channels. A normalized RF shimming field parameter may be denoted as ω=[ω₁, ω₂, . . . , ωₙ], where each channel may normalize channel 1, i.e.,

$${ω}_{1} = 1 ; {ω}_{2} = \frac{{A}_{2}}{{A}_{1}} {e}^{j ( {ϕ}_{2} - {ϕ}_{1} )} ; … … ; {ω}_{n} = \frac{{A}_{n}}{{A}_{1}} {e}^{j ( {ϕ}_{n} - {ϕ}_{1} )} .$$

The SAR (r) corresponding to any position r in the target object may be determined according to the following equation (1).

$$S A R ( r ) = \frac{1}{V} \int \frac{σ ( r )}{2 ρ ( r )} {\vert E ( r ) \vert}^{2} d v = \frac{1}{V} \int \frac{σ ( r )}{2 ρ ( r )} {( {\sum }_{i = 1}^{n} {\overline{E}}_{i} ( r ) \times {w}_{i} )}^{H} \cdot ( {\sum }_{i = 1}^{n} {\overline{E}}_{i} ( r ) \times {w}_{i} ) dv = {w}^{H} \cdot \frac{1}{V} \int \frac{σ ( r )}{2 ρ ( r )} ( {\overline{E}}^{H} ( r ) \times \overline{E} ( r ) ) dv \cdot w = {w}^{H} \cdot Q ( r ) \cdot w \qquad ( 1 )$$

where r denotes different positions, a certain position point in the target object may be characterized in Cartesian coordinates as x, y, and z directions, i.e., SAR(x, y, z)=w^{H}. Q(x, y, z)·w, and a local SAR of 10 g around the position r may be calculated by the above equation (1). V denotes a volume of the target object, σ(r) denotes a conductivity of a body model at the position r, ρ(r) denotes a density of the body model at the position r. Ē(r)=E̅₁̅(̅r̅)̅, E̅₂̅(̅r̅)̅ . . . . . . E̅ₙ̅(̅r̅)̅, and Ē(r) is electric field complex vectors generated by a unit excitation of the RF channels. The superscript H denotes a conjugate transpose. Q(r) represents a sensitivity distribution matrix (which is also referred to as a Q-matrix) corresponding the point r, and the sensitivity distribution matrix Q (r) is an n°n positive definite matrix, wherein n denotes a count of the RF channels, wᵢ denotes the RF shimming field parameter of the ith RF channel, and w denotes the normalized RF shimming field parameter.

Based on the above equation (1), the computer device may perform integration within different volumes V to yield the sensitivity distribution matrices of different tissue regions.

For example, by integrating over a volume of the head range of the target object, a head sensitivity distribution matrix is obtained; by integrating over a volume of a whole body range, a whole-body sensitivity distribution matrix is obtained; by integrating over a volume of a body exposed region, a partial body sensitivity distribution matrix is obtained; and by integrating within a volume of 10 g of body tissue, a local sensitivity distribution matrix within the 10 g of body tissue is obtained.

Combined with a form of the expression equation, it may be seen that the sensitivity distribution matrix Q(r) is irrelavent to the RF shimming field parameter w, but is related to a single-channel excitation electric field of the RF coil, and the conductivity and the density of the human tissue. Therefore, the sensitivity distribution matrix Q (r) may be obtained, independently from the RF shimming field parameter, by electromagnetic field simulation and calculation in advance. In this way, using equation (1), the SAR corresponding to any RF shimming field parameter w may be easily calculated based on the normalized RF shimming field parameter w and the sensitivity distribution matrix Q(r). By specifying a different integration region, a whole-body SAR, a head SAR, a partial body SAR, or a partial SAR under a certain RF shimming field parameter w may also be calculated.

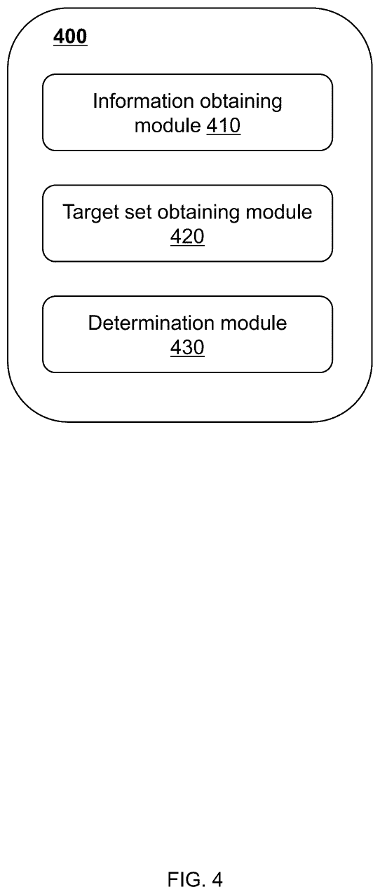

FIG. 4 is a block diagram illustrating an exemplary system for determining an SAR according to some embodiments of the present disclosure.

In some embodiments, an SAR determination system 400 includes an information obtaining module 410, a target set obtaining module 420, and a determination module 430 as shown in FIG. 4.

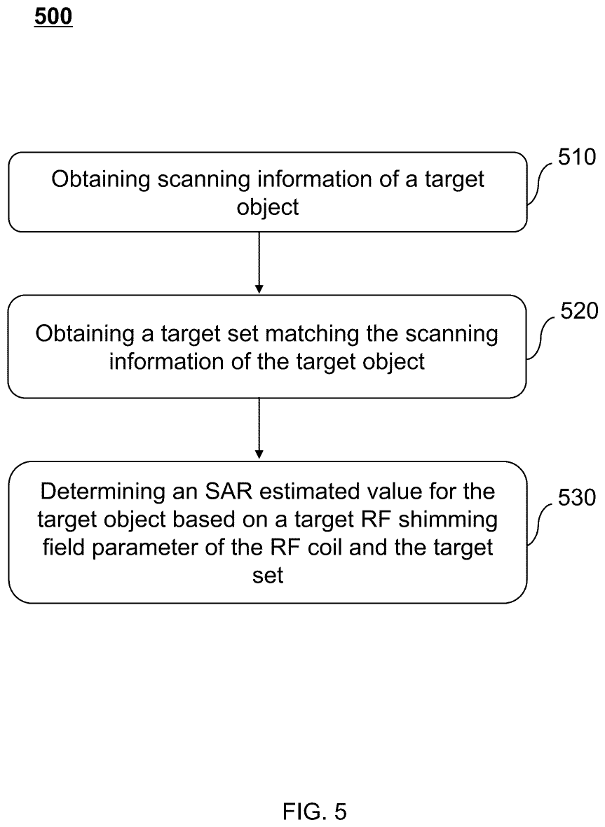

The information obtaining module 410 is configured to obtain scanning information of a target object, and the scanning information includes a physiological feature of the target object and position information of an RF coil in an MR device. For a more detailed description of the scanning information, see the related description of FIG. 5.

The target set obtaining module 420 is configured to obtain a target set matching the scanning information of the target object, and the target set includes a plurality of target sensitivity distribution matrices corresponding to a first count of target local hotspots. The first count of target local hotspots are selected from a second count of initial local hotspots on a body model, and the second count is greater than the first count

The determination module 430 is configured to determine an SAR estimated value for the target object based on an RF shimming field parameter of the RF coil and the target set.

More contents on the target set, the SAR estimated value may be found in the related descriptions of FIGS. 5-9.

It should be noted that the above descriptions of the SAR estimation system 400 and the modules thereof are provided only for descriptive convenience, and do not limit the present disclosure to the scope of the cited embodiments. It is understood that for those skilled in the art, with an understanding of the principle of the device, it may be possible to arbitrarily combine the individual modules, or form sub-devices to be connected to the other modules without departing from the principle. In some embodiments, the information obtaining module 410, the target set obtaining module 420, and the determining module 430 in FIG. 4 are different modules in a single device, or a single module realizes functions of the aforementioned two or more modules. For example, the modules share a same storage module, or the modules each has a respective storage module. Morphisms such as these are within a scope of protection of the present disclosure.

FIG. 5 is a flowchart illustrating an exemplary method for determining an SAR according to some embodiments of the present disclosure. In some embodiments, a process 500 is performed by a computer device. The process 500 includes operations 510-530.

In 510, the computer device obtains scanning information of a target object.

The scanning information refers to data information related to MRI scanning of the target object.

In some embodiments, the scanning information includes a physiological feature of the target object and position information of an RF coil in an MR device.

The physiological feature refers to a physiological parameter that affects a distribution of an electromagnetic field. For example, the physiological feature includes a height, a weight, an age, etc.

The position information of the RF coil refers to a spatial position of the RF coil relative to the target object, or a relative geometric relationship between the RF coil and a scanning portion of the target object. The RF coil refers to a component of the MR device that is used to transmit and receive RF signals. The RF signals refer to electromagnetic signals emitted by the MR device.

In some embodiments, the computer device obtains the physiological feature of the target object and the position information of the RF coil in the MR device in various manners.

For example, the computer device obtains the physiological feature of the target object of registration information of the target object directly from the storage device or obtains the physiological feature of the target object by taking measurements prior to the MRI scanning.

For example, the computer device obtains information about the position of the RF coil by reading a configuration file of the MR device.

As another example, the computer device obtains the RF signals fedback from a body portion of the target object based on the RF coil by performing pre-scanning on the target object, determines the position information of the target object based on the RF signals fed back from the body portion of the target object, determines the position information of the RF coil based on the position information of the target object. The pre-scanning refers to a low-power, fast, and short-sequence scanning process performed on the target object prior to the MRI scanning. In some embodiments, the computer device pre-scans the target object based on a low-power (e.g., 300-watt) RF signal by controlling the MR device.

As another example, the computer device presets the position information of the RF coil in a three-dimensional (3D) electromagnetic field simulation.

The embodiments of the present disclosure do not limit the manner in which the scanning information is obtained.

In 520, the computer device obtains a target set matching the scanning information of the target object.

In some embodiments, the target set includes a plurality of target sensitivity distribution matrices corresponding to a plurality of target local hotspots.

In some embodiments, the target set includes a plurality of target sensitivity distribution matrices corresponding to a first count of target local hotspots. Exemplarily, the target set includes I target local hotspots denoted as target local hotspot 1˜target local hotspot I, and I target sensitivity distribution matrices denoted as target sensitivity distribution matrix 1˜target sensitivity distribution matrix I. Each of the I target sensitivity distribution matrices corresponds to one of the I target local hotspots. I is an integer greater than 1. In order to balance accuracy and facilitate engineering calculations, I may be tens to thousands. I is the first count.

In some embodiments, the first count of target local hotspots are selected from a second count of initial local hotspots on a body model, and the second count is greater than the first count.

It should be noted that equation (1) determines the SAR of a region by integrating over the entire region, which is equivalent to averaging the SARs over the region. This embodiment is able to further simplify the integration calculation of the volume V (as in equation (1)) in the conventional manner to monitoring of key hotspots by selecting the first count of target local hotspots from the second count of initial local hotspots on the body model so as to select positions that are likely to produce the highest SAR, instead of calculating the average SAR of the region, thereby reducing an amount of computation.

The target set may be a set stored in advance in the computer device or a set that the computer device is able to read in real time from another device or storage, and this embodiment is not limited thereto.

To facilitate the calculation of the SAR at various positions of the body, the body model may be divided into a plurality of pixel points or grid points. The local positions are discrete pixel points or discrete grid points into which the human body is divided for calculating the SAR. The second count of initial local hotspots are capable of covering all regions on the body. The target local hotspots are positions selected from the second count of initial local hotspots that are most likely to generate the greatest SAR, and the first count is a count of the positions selected from the second count of initial local hotspots that are most likely to generate the greatest SAR.

In some embodiments, the first count of target local hotspots and the second count of initial local hotspots are determined by simulation screening.

In some embodiments, the second count is in an order of millions and the first count is in an order of tens to thousands.

The first count and the second count may be system default values, empirical values, human pre-set values, etc. or any combination thereof, which are set according to an actual demand, and the present disclosure does not limit this.

The target sensitivity distribution matrix refers to a sensitivity distribution matrix corresponding to a target local hotspot.

The sensitivity distribution matrix refers to a matrix that reflects a correspondence between a change in a tissue conductivity distribution within the target object and a change in an induced electric field in the RF coil. The sensitivity distribution matrix is configured to characterize an absorption feature of an RF energy by the target object at a specific position. The SAR corresponding to the sensitivity distribution matrix is determined by substituting the sensitivity distribution matrix and the RF shimming field parameter into equation (1).

The tissue conductivity refers to a parameter used to characterize an ability for human tissue to conduct the RF signals.

In some embodiments, the sensitivity distribution matrix quantifies the absorption power of the RF signals in different human tissue regions.

In some embodiments, the sensitivity distribution matrix is correlated to a tissue conductivity, a tissue density, and a spatial distribution of the body model. The tissue density refers to a density of the body model (e.g., a mass of the body model per unit volume). For example, the sensitivity distribution matrix is constructed based on the tissue conductivity of the body model and the spatial distribution of the RF signals in the body model.

In some embodiments, the computer device analyzes relevant information of the target object during the scanning process of the MR device based on a calculation manner of the sensitivity distribution matrix to determine the sensitivity distribution matrix of the target object, or, a plurality of different types of sensitivity distribution matrices are stored in a database, and the computer device utilizes the relevant information of the target object during the scanning process of the MR device to respectively match the plurality of different types of sensitivity distribution matrices, and the successfully matched sensitivity matrix is used as the sensitivity distribution matrix of the target object. The embodiments of the present disclosure do not impose any limitation on the manner of obtaining the sensitivity distribution matrix of the target object.

The target local hotspot refers to a position in the target object that absorbs a higher amount of RF energy during the scanning of the MR device. For example, the target local hotspot is a position that absorbs the highest RF energy. As another example, the target local hotspot is a position where the absorbed RF energy is higher than surrounding tissues.

In connection with equation (1), it may be seen that the positions in a simulation object are in a one-to-one correspondence with the sensitivity distribution matrices, so each target local hotspot corresponds to a target sensitivity distribution matrix.

In some embodiments, the computer device determines the second count of initial local hotspots in the simulation object and the sensitivity distribution matrices corresponding to the second count of initial local hotspots; and then selects the first count of target local hotspots.

After determining the second count of initial local hotspots and the sensitivity distribution matrices corresponding to the second count of initial local hotspots, the computer device may determine the first count of target local hotspots based on classification of a scanning portion.

For example, when the scanning portion is a head, or a chest, etc., the computer device selects a plurality of local positions corresponding to the head, or the chest from the second count of initial local hotspots, and the sensitivity distribution matrices corresponding to the plurality of selected local positions.

In some embodiments, the first count of target local hotspots are a collection of positions determined based on clustering of a plurality of initial local hotspots. More detailed descriptions of the clustering may be found in the related description later.

The initial local hotspot refers to a position to be determined as a target local hotspot. More detailed descriptions of the initial local hotspot may be found in the related description later.

In some embodiments, the plurality of initial local hotspots are selected from the second count of initial local hotspots. For example, the computer device selects, from the the initial local hotspots. A count of the initial local hotspots is also referred to as a third count. The third count is less than or equal to the second count.

In some embodiments, the computer device determines object candidate positions of one or more simulation objects and a candidate sensitivity distribution matrix corresponding to each object candidate position; and for each candidate RF shimming field parameter, the computer device determines an initial local hotspot corresponding to the candidate RF shimming field parameter based on the candidate sensitivity distribution matrix corresponding to each object candidate position and the candidate RF shimming field parameter.

There may be one or more simulation objects.

The object candidate positions refer to various position points in the one or more simulation objects. A count of the object candidate positions is an integer N greater than 1. For example, N may be in an order of millions.

Alternatively, the computer device may model the simulation object to obtain at least one model corresponding to the simulation object, and determine N discrete object candidate positions from the model. For example, taking the simulation object being the body as an example, through a coil modeling and a 3D electromagnetic field joint simulation on the human body model, the computer device obtains the body model and N object candidate positions at different positions of the human body model relative to the coil, as well as the candidate sensitivity distribution matrix Q(x, y, z) corresponding to each of the N object candidate positions. The object candidate position may be represented by Cartesian coordinates, and the computer device calculates the sensitivity distribution matrix Q(x, y, z) corresponding to the position through the object candidate position Q(x, y, z). N is the second count.

After determining the object candidate positions, the computer device may determine the candidate sensitivity distribution matrix corresponding to each object candidate position, denoted as candidate sensitivity distribution matrix 1˜candidate sensitivity distribution matrix N.

The candidate sensitivity distribution matrix refers to a sensitivity distribution matrix corresponding to an object candidate position.

In some embodiments, based on the object candidate position, the computer device calls a preset sensitivity distribution matrix for the corresponding position from the memory.

The candidate RF shimming field parameter refers to an RF shimming field parameter that is used during the scanning process of a medical scanning device. The medical scanning device may include, but not limited to, an MRI device.

The RF shimming field parameter may include an amplitude ratio parameter and a phase difference parameter. The amplitude ratio parameter is a ratio of an emission amplitude of each channel relative to a reference channel (usually channel 1). The phase difference parameter is an offset of the emission phase of each channel relative to the reference channel.

In some embodiments, the computer device determines the candidate RF shimming field parameters from a historical scanning record of the medical scanning device, or randomly generates a plurality of candidate RF shimming field parameters, which is not limited by this embodiment.

In some embodiments, the computer device determines the candidate RF shimming field parameters by the following operations S11-S12.

In S11, the computer device obtains an initial RF shimming field parameter.

In this embodiment, the computer device is capable of obtaining the initial RF shimming field parameter. The initial RF shimming field parameter also includes the RF shimming field parameter corresponding to each RF channel, e.g., the initial RF shimming field parameter is the normalized RF shimming field parameter described above.

Alternatively, the computer device may receive the initial RF shimming field parameter sent by the medical scanning device or the other devices, or may receive the initial RF shimming field parameter input by a user, or may simulate and generate the initial RF shimming field parameter, which are not limited in this embodiment.

In S12, the computer device processes the initial RF shimming field parameter to obtain the object candidate positions in the simulation object and the candidate RF shimming field parameter corresponding to each object candidate position.

Alternatively, in this embodiment, the computer device may process the initial RF shimming field parameter at a certain interval to obtain the plurality of candidate RF shimming field parameters. Exemplarily, assuming that a multi-channel system has n emission channels and the initial RF shimming field parameter ω=[A₁(Ø₁), A₂(Ø₂), . . . Aₙ(Øₙ)], then the computer device divides an emission magnitude Aₙ of the emission channel from 0 to 1 and a phase Øₙ of the emission channel from 0 to 360 degrees into M equal parts for arbitrary combinations in order to obtain the candidate RF shimming field parameters.

Alternatively, the computer device may also limit a range of the initial RF shimming field parameter or a count of shimming patterns to obtain the candidate RF shimming field parameters. Alternatively, the computer device may also process the initial RF shimming field parameter based on a certain count of random excitations to obtain the candidate RF shimming field parameters.

Alternatively, a count of the initial RF shimming field parameters may be less than the count of candidate RF shimming field parameters. That is, the process of processing the initial RF shimming field parameter may also be understood as a process of diversifying the initial RF shimming field parameter to improve richness of the candidate RF shimming field parameters.

In the above embodiment, as the initial RF shimming field parameter is obtained and processed, richness and diversification of the candidate RF shimming field parameters are obtained, which is conducive to improving accuracy of the initial local hotspots.

For each candidate RF shimming field parameter among K candidate RF shimming field parameters, the computer device determines the initial local hotspot corresponding to the candidate RF shimming field parameter based on the N candidate sensitivity distribution matrices corresponding to the N object candidate positions and the candidate RF shimming field parameter. The initial local hotspots are denoted as initial local hotspot 1˜initial local hotspot K. The initial local hotspot refers to a position where the RF energy is absorbed at a higher level in the simulated object under an action of a candidate RF shimming field parameter. For example, the initial local hotspot is a position that absorbs the highest RF energy. K is the third count.

As an example, for a candidate RF shimming field parameter 1, the computer device determines an initial local hotspot 1 corresponding to the candidate RF shimming field parameter 1 based on the candidate sensitivity distribution matrix 1˜candidate sensitivity distribution matrix N, and the candidate RF shimming field parameter 1. For a candidate RF shimming field parameter 2, the computer device determines an initial local hotspot 2 corresponding to the candidate RF shimming field parameter 2 based on the candidate sensitivity distribution matrix 1˜candidate sensitivity distribution matrix N, and the candidate RF shimming field parameter 1. By analogy, the computer device may determine K initial local hotspots corresponding to K candidate RF shimming field parameters, respectively.

In some embodiments, the computer device determines the initial local hotspots by the following operations S21-S22.

In S21, for each candidate RF shimming field parameter, the computer device determines a candidate SAR corresponding to each candidate sensitivity distribution matrix based on the candidate RF shimming field parameter, the candidate sensitivity distribution matrix, and the corresponding object candidate position in the simulation object.

Continuing with the above example, for the candidate RF shimming field parameter 1, the computer device determines the candidate SAR corresponding to each candidate sensitivity distribution matrix based on the candidate sensitivity distribution matrix 1˜candidate sensitivity distribution matrix N and the candidate RF shimming field parameter 1. For example, the computer device substitutes the candidate sensitivity distribution matrix 1 and the candidate RF shimming field parameter 1 into equation (1) to determine a candidate SAR1 corresponding to the candidate sensitivity distribution matrix 1, substitutes the candidate sensitivity distribution matrix 2 and the candidate RF shimming field parameter 2 into equation (1) to determine the candidate SAR2 corresponding to the candidate sensitivity distribution matrix 2, and so on, to determine N candidate SARs corresponding to the N candidate sensitivity distribution matrices.

Similarly, for the candidate RF shimming field parameter 2, the computer device determines the candidate SAR corresponding to each candidate sensitivity distribution matrix based on candidate sensitivity distribution matrix 1˜candidate sensitivity distribution matrix N and the candidate RF shimming field parameter 2. By analogy, for each candidate RF shimming field parameter, N candidate SARs corresponding to N candidate sensitivity distribution matrices may be determined.

In S22, the computer device determines the initial local hotspot corresponding to the candidate RF shimming field parameter based on the candidate SAR corresponding to each candidate sensitivity distribution matrix.

Alternatively, in this embodiment, for each candidate RF shimming field parameter, the computer device may take the object candidate position corresponding to the greatest candidate SAR among the N candidate SARs as the initial local hotspot, or take the object candidate position corresponding to the candidate SAR greater than an SAR threshold in the N candidate SARs as the initial local hotspot, or use the object candidate position corresponding to an SAR that is at a preset ranking among the N candidate SARs as the initial local hotspot, which are not limited in this embodiment.

Taking the candidate RF shimming field parameter 1 as an example, the computer device determines N candidate SARs corresponding to the N candidate sensitivity distribution matrices based on the candidate sensitivity distribution matrix 1˜candidate sensitivity distribution matrix N and the candidate RF shimming field parameter 1, and afterwards, the computer device determines the initial local hotspot corresponding to the candidate RF shimming field parameter 1 based on the N candidate SARs. Assuming that among the N candidate SARs, a candidate SAR 3 corresponding to a candidate sensitivity distribution matrix 3 is at a preset ranking, and the candidate sensitivity distribution matrix 3 corresponds to an object candidate position 3, that is, the candidate SAR 3 corresponds to the object candidate position 3, then the computer device may take the object candidate position 3 as the initial local hotspot corresponding to the candidate RF shimming field parameter 1.

The other candidate RF shimming field parameters are processed similarly, and are not repeated here. In this way, for each candidate RF shimming field parameter, the initial local hotspot corresponding to the candidate RF shimming field parameter may be determined based on the candidate SAR corresponding to each candidate sensitivity distribution matrix.

In the above embodiment, since for each candidate RF shimming field parameter, it is possible to determine the candidate SAR corresponding to each candidate sensitivity distribution matrix based on the candidate RF shimming field parameter and the candidate sensitivity distribution matrices. In this way, the initial local hotspot corresponding to the candidate RF shimming field parameter may be determined based on the candidate sensitivity distribution matrices.

In an exemplary embodiment, the above-described S22 is realized in the following manner: the object candidate position corresponding to the greatest candidate SAR is taken as the initial local hotspot corresponding to the candidate RF shimming field parameter.

In this embodiment, continuing to take the candidate RF shimming field parameter 1 as an example, the computer device determines the candidate SAR 1 based on the candidate RF shimming field parameter 1 and the candidate sensitivity distribution matrix 1 corresponding to the object candidate position 1, and determines the candidate SAR 2 based on the candidate RF shimming field parameter 1 and the candidate sensitivity distribution matrix 2 corresponding to the object candidate position 2, and so on, to determine the N candidate SARs. Assuming that the candidate SAR3 is the maximum value, the object candidate position corresponding to the greatest candidate SAR is the object candidate position 3, the computer device uses the object candidate position 3 as the initial local hotspot corresponding to the candidate RF shimming field parameter 1. The other candidate RF parameters are processed similarly, and are not repeated here.

In the above embodiment, the object candidate position corresponding to the greatest candidate SAR under each of the candidate RF shimming field parameters indicates a position that is the most likely to generate a high SAR value among all the object candidate positions, and the object candidate position is taken as the initial local hotspot. In this way, the accuracy of the initial local hotspot is improved.

In some embodiments, the computer device directly determines the initial local hotspot corresponding to each of the plurality of candidate RF shimming field parameters as the plurality of target local hotspots.

In further embodiments, the computer device clusters the initial local hotspots corresponding to the plurality of candidate RF shimming field parameters to obtain the plurality of target local hotspots. For example, the computer device clusters a third count of initial local hotspots to obtain a first count of target local hotspots. The first count is less than the third count, i.e., a count of the target local hotspots is less than a count of the initial local hotspots.

Exemplarily, the computer device clusters the initial local hotspots based on, including but not limited to, a Gaussian mixture model, a density clustering method, spectral clustering, etc., to obtain the target local hotspots.

In some embodiments, as the local hotspots have a correspondence with the sensitivity distribution matrices, after determining the first count of target local hotspots, the computer device determines the first count of target sensitivity distribution matrices corresponding to the first count of target local hotspots, respectively, and thus, the computer device determines the target set.

Alternatively, the computer device may store the target set, i.e., store the first count of the target sensitivity distribution matrices, so that subsequently, after obtaining the target RF shimming field parameter, an SAR estimated value is determined directly based on the target RF shimming field parameter and the stored target set.

In the above embodiment, as the object candidate positions in the simulation object and the candidate sensitivity distribution matrices corresponding to each object candidate position are determined, for each candidate RF shimming field parameter, the initial local hotspot corresponding to the candidate RF shimming field parameter is determined based on the candidate sensitivity distribution matrix corresponding to each object candidate position and the candidate RF shimming field parameter. After that, the computer device clusters the initial local hotspots, and target local hotspots with a smaller count may be obtained, and then, after determining the target set based on the target local hotspots and the corresponding target sensitivity distribution matrices, the computer device may quickly determine the SAR estimation value corresponding to the target RF shimming field parameter directly based on the target RF shimming field parameter and the target set, which improves an efficiency of SAR determination.

In operation 530, the computer device determines an SAR estimated value for the target object based on a target RF shimming field parameter of the RF coil and the target set.

The SAR estimated value refers to a parameter that describes an absorption of the RF signals by biological tissue. In some embodiments, the SAR may be an RF signal energy absorbed by the unit mass of the tissue of the target object. The tissue may be a whole body, a head, a part of the body, or 10 g of the body tissue, etc. of the target object.

The target RF shimming field parameter refers to an RF shimming field parameter for which the SAR needs to be calculated. For example, the target RF shimming field parameter is an RF shimming field parameter used by the medical scanning device during scanning.

The target RF shimming field parameter includes the corresponding RF shimming field parameter of each RF channel, for example, the target RF shimming field parameter is the normalized RF shimming field parameter described above.

The target RF shimming field parameter is capable of being actuated by a multi-channel RF transmission coil of the MR system. A count of RF channels of the transmission coil may be, for example, 4, 8, 16, or more. In other words, the target RF shimming field parameter is applied through the plurality of transmission channels of the transmission coils to the detection object, and the detection object is an object that is about to be, or is in a process of being scanned and detected in the MRI scanning.

Alternatively, the computer device may receive the target RF shimming field parameter sent by the medical scanning device or other devices, and in some embodiments, the computer device also receives the target RF shimming field parameter input by a user, or, the computer device also perform simulation to generate the target RF shimming field parameter, which are not limited in this embodiment.

After obtaining the target RF shimming field parameter, the computer device may determine the SAR estimated value corresponding to the target RF shimming field parameter based on the target RF shimming field parameter and the target set.

Alternatively, the computer device may determine the greatest SAR as the SAR estimated value based on the target RF shimming field parameter and each target sensitivity distribution matrix. Continuing with the above example, the computer device calculates an SAR1 by substituting the target RF shimming field parameter and the target sensitivity distribution matrix 1 into equation (1), calculates an SAR2 by substituting the target RF shimming field parameter and the target sensitivity distribution matrix 2 into equation (1), and so on. The computer device obtains I SARs, and assuming that SAR2 is the greatest of the I SARs, the computer device may use the SAR2 as the SAR estimated value.

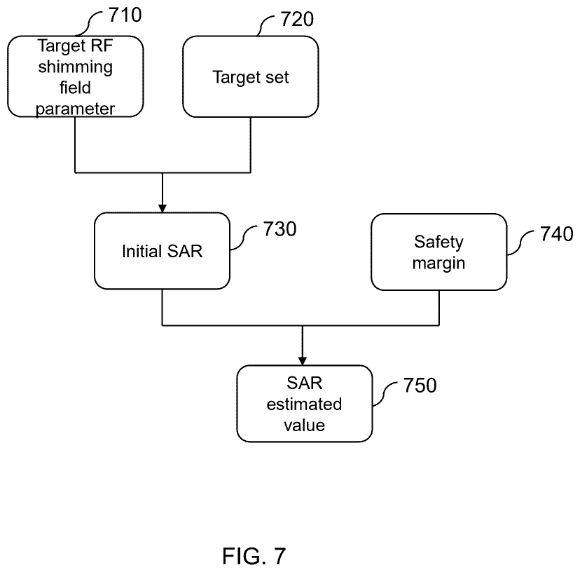

More contents on determining the SAR estimated value may be found in FIG. 7 and the associated descriptions.

In the above SAR estimation manner applied to the MR scanning, as the target set includes the target sensitivity distribution matrices corresponding to the plurality of target local hotspots, and the target set includes a plurality of initial local hotspots, or is a set determined by clustering the plurality of initialized local hotspots, a count of the target local hotspots is smaller than a count of the object candidate positions on the simulation object, so there is no need to store the sensitivity distribution matrix and calculate the corresponding local SAR for each object candidate position, instead, the target RF shimming field parameter may be obtained to quickly determine the SAR estimated value corresponding to the target RF shimming field parameter directly based on the target RF shimming field parameter and the target set, which improves the efficiency of SAR determination.

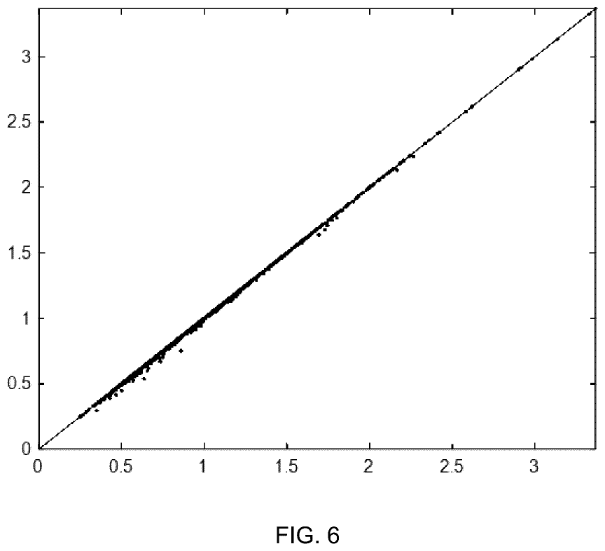

FIG. 6 is a schematic diagram illustrating exemplary estimation effects of two SAR estimated values according to some embodiments of the present disclosure. As shown in FIG. 6, a horizontal coordinate indicates a result of SAR estimation using hotspots of all voxels, and the vertical coordinate indicates a result of SAR estimation using hotspots of partial voxels. A count of all voxels is about 720,000, and a count of the partial voxels is 150. That is, the vertical coordinates indicate the SAR estimation values calculated by simulation after clustering, and the horizontal coordinates indicate the SAR estimation values calculated by simulation for all the voxels of a simulation object. As shown in FIG. 6, the results of SAR estimated values calculated by the two manners are comparable, i.e., the results obtained by clustering voxels are nearly linear to the results obtained by using all voxels. As can be seen, the present disclosure, on the basis of clustering, on the one hand, reduces a count of target local hotspots and improves a speed of SAR determination, and on the other hand, does not degrade accuracy of SAR determination, and has a high estimation precision.

FIG. 7 is a schematic diagram illustrating an exemplary process for determining an SAR estimated value according to some embodiments of the present disclosure.

In some embodiments, as shown in FIG. 7, the computer device determines an initial SAR 730 corresponding to a target RF shimming field parameter 710 based on the target RF shimming field parameter 710 and a target set 720, and determines an SAR estimated value 750 based on a safety margin 740 and the initial SAR 730. The initial SAR refers to an initially determined SAR.

In some embodiments, the computer device selects the greatest value among all the specific absorption rates (SARs) as the initial SAR based on the target RF shimming field parameter and each target sensitivity distribution matrix. Merely by way of example, the computer device calculates SAR1 by substituting the target RF shimming field parameter and a target sensitivity distribution matrix 1 into the equation (1), calculates SAR2 by substituting the target RF shimming field parameter and a target sensitivity distribution matrix 2 into the equation (1), and so forth, the computer device may obtain a first count of SARs, and assuming that SAR2 is the greatest value among all the first count of SARs, the computer device may select SAR2 as the initial SAR.

In some embodiments, for each target local hotspot, the computer device calculates an SAR for the target local hotspot based on the target RF shimming field parameter and the corresponding target sensitivity distribution matrix, and selects the greatest value among all the SARs as the initial SAR. Merely by way of example, the computer device calculates SAR1 by substituting the target RF shimming field parameter and a target sensitivity distribution matrix 1 into the formula (1), calculates SAR2 by substituting the target RF shimming field parameter and a target sensitivity distribution matrix 2 into the formula (1), and so forth, the computer device may obtain a plurality of SARs, and assuming that SAR2 is the greatest value among the plurality of SARs, the computer device may select SAR2 as the initial SAR.

In some embodiments, the computer device may further determine a region to be scanned for the target object, determine one or more target positions corresponding to the region to be scanned from the first count of target local hotspots, and determine the initial SAR corresponding to the target RF shimming field parameter based on the target RF shimming field parameter and the one or more target positions.

The region to be scanned refers to a specific part of the target object that is about to be subjected to an MR scan. For example, the region to be scanned may be the head, the abdomen, the chest, or the like.

The region to be scanned may be preset based on a scanning protocol or a physician's order.

In some embodiments, the first count of target local hotspots include target local hotspots located outside the region to be scanned for the target object. For example, when the region to be scanned is the head of the target object, the first count of target local hotspots include target local hotspots located at the abdomen and the chest of the target object.

The target position refers to a position matching the region to be scanned among the target local hotspots.

In some embodiments, the computer device determines the one or more target positions corresponding to the region to be scanned from the first count of target local hotspots by Cartesian spatial coordinate matching. For example, when performing a head scan, the computer device matches target local hotspots across the whole body with coordinates of the region to be scanned in the head, retaining only target local hotspots that are successfully matched in the head and ignoring other hotspots, such as hotspots located at the abdomen.

As another example, the computer device specifies an anatomical range to be scanned for the target object according to a scanning protocol (e.g., “head MRI”), and retrieves a “target local hotspot list” from a database to select target local hotspots related to the region to be scanned for the target object.

In some embodiments, the computer device may calculate an SAR corresponding to each of the one or more target positions by the formula (1) based on the target RF shimming field parameter and the target sensitivity distribution matrix corresponding to each of the one or more target positions, and select the greatest value among all the SARs as the initial SAR.

In this embodiment, since the initial SAR is determined based on the target set, and the target set is determined based on clustering of a plurality of initial local hotspots, it is not capable of traversing SARs for all positions. Therefore, to improve the reliability of the SAR estimated value, the computer device may determine a safety margin. The safety margin may be understood as a protection mechanism to prevent potential safety issues that may arise from the underestimation of the SAR estimated value.

In some embodiments, the computer device may receive a user-inputted safety margin or may calculate the safety margin on its own, which is not limited in this embodiment.

In some embodiments, the computer device may determine a scanning position of the target object and select the safety margin from a plurality of candidate safety margins based on the scanning position.

The scanning position refers to a tissue, organ, etc., inside the body of the target object.

In some embodiments, the computer device may determine the scanning position of the target object from the scanning protocol.

In some embodiments, the computer device may determine candidate safety margins corresponding to different scanning positions by simulation and construct a comparison table. The comparison table includes a correspondence between different scanning positions and candidate safety margins. The computer device may look up a candidate safety margin corresponding to a scanning position identical to the scanning position of the target object in the comparison table based on the scanning position of the target object, and determine the candidate safety margin as a currently required safety margin.

In this embodiment, the safety margin is determined based on different scanning positions of the human body, and the safety margin may be appropriately reduced for the insensitive parts under the premise of satisfying the safety specification.

In some embodiments, the computer device may further determine the safety margin based on the object candidate positions of the simulation object, the candidate sensitivity distribution matrix corresponding to each object candidate position, and the target sensitivity distribution matrices corresponding to the first count of target local hotspots. For example, the computer device may determine the safety margin based on candidate sensitivity distribution matrix 1 to candidate sensitivity distribution matrix N and target sensitivity distribution matrix 1 to target sensitivity distribution matrix I.

In some embodiments, the computer device may determine the safety margin based on the object candidate positions of the simulation object, the candidate sensitivity distribution matrix corresponding to the each object candidate position, and the target sensitivity distribution matrices corresponding to the first count of target local hotspots through a prediction model trained in advance. For example, the computer device may input the candidate sensitivity distribution matrix 1 to the candidate sensitivity distribution matrix N and the target sensitivity distribution matrix 1 to the target sensitivity distribution matrix I into the prediction model, and the prediction model outputs the corresponding safety margin.

In some embodiments, the prediction model may be a machine learning model. For example, the prediction model may include any one or a combination of a Convolutional Neural Network (CNN) model, a Neural Network (NN) model, or other custom models.

In some embodiments, the prediction model may be obtained by training a plurality of first training samples each of which is with a first training label. The first training sample includes a candidate sensitivity distribution matrix sample and a target sensitivity distribution matrix sample, and the first label is a label of a safety margin.

The computer device may perform the following training process to obtain the prediction model. The training process includes: obtaining a plurality of first training samples each of which is with a first label to form a first training sample set, and performing a plurality of iterations based on the first training sample set. At least one iteration among the plurality of iterations includes: selecting one or more first training samples from the first training sample set, inputting the one or more first training samples into an initial prediction model, obtaining a prediction output corresponding to the one or more first training samples from the initial prediction model; substituting the prediction output corresponding to the one or more first training samples and the first labels corresponding to the one or more first training samples into a formula for a predefined loss function, calculating a value of the loss function; iteratively updating a model parameter of the initial prediction model based on the value of the loss function until a termination condition is satisfied, terminating the iteration, and obtaining the trained prediction model. The iterative updating of the model parameter of the initial prediction model may be carried out by a variety of methods, e.g., it may be carried out based on the gradient descent method. The termination condition may include the loss function converging or a count of iterations reaching an iteration count threshold, etc.

In some embodiments, the computer device may determine the safety margin according to operations S31 to S33.

In operation S31, the computer device determines a first SAR based on object candidate positions of a simulation object and a candidate sensitivity distribution matrix corresponding to each object candidate position.

In this embodiment, the computer device is capable of determining the first SAR based on the candidate sensitivity distribution matrix 1 to the candidate sensitivity distribution matrix N. Merely by way of example, for each candidate RF shimming field parameter, the computer device may determine the greatest value among all SARs or the average value of all SARs corresponding to the candidate sensitivity distribution matrices as the first SAR based on the candidate RF shimming field parameter and each candidate sensitivity distribution matrix.

In operation S32, the computer device determines a second SAR based on target sensitivity distribution matrices corresponding to a first count of target local hotspots.

In this embodiment, the computer device is also capable of determining the second SAR based on the target sensitivity distribution matrix 1 to the target sensitivity distribution matrix I. Merely by way of example, for each candidate RF shimming field parameter, the computer device may determine the greatest value among all SARs or the average value of all SARs corresponding to the target sensitivity distribution matrices as the second SAR based on the candidate RF shimming field parameter and each target sensitivity distribution matrix.

In operation S33, the computer device determines a safety margin based on a difference between the first SAR and the second SAR.

In this embodiment, the difference between the first SAR and the second SAR may include, but is not limited to, an absolute difference, a relative difference, or a percentage difference between the first SAR and the second SAR. For example, the computer device may determine the difference or quotient between the first SAR and the second SAR as the safety margin.

In the above embodiment, since the first SAR is determined based on each candidate sensitivity distribution matrix and the second SAR is determined based on each target sensitivity distribution matrix, by utilizing the difference between the first SAR and the second SAR, the safety margin can be determined more accurately based on each candidate sensitivity distribution matrix and each target sensitivity distribution matrix.

In the above embodiment, since the safety margin is determined based on each candidate sensitivity distribution matrix and each target sensitivity distribution matrix, and the initial SAR is obtained based on the target RF shimming field parameter, a more accurate SAR estimated value can be determined based on the safety margin and the initial SAR.

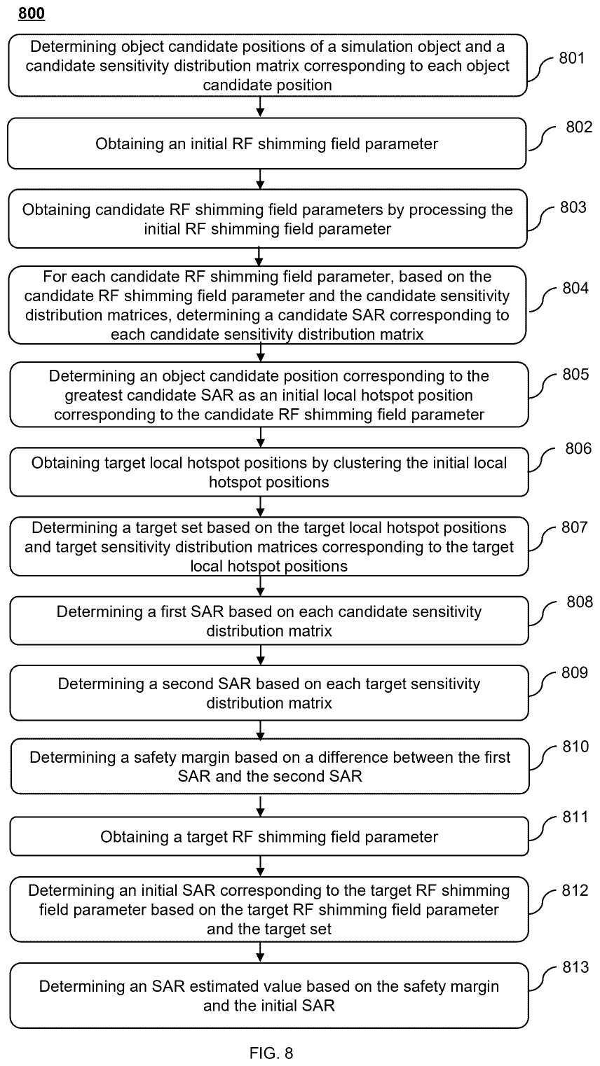

To more clearly introduce a method for determining an SAR estimated value applied to an MR scan, it is described herein in conjunction with FIG. 8. FIG. 8 is a flowchart illustrating an exemplary process for determining an SAR estimated value applied to an MR scanning according to one embodiment of the present disclosure. As shown in FIG. 8, a computer device may execute the method for determining an SAR estimated value applied to an MR scanning as follows.

In operation 801, the computer device determines object candidate positions of a simulation object and a candidate sensitivity distribution matrix corresponding to each object candidate position.

In operation 802, the computer device obtains an initial RF shimming field parameter.

In operation 803, the computer device obtains candidate RF shimming field parameters by processing the initial RF shimming field parameter.

In operation 804, for each candidate RF shimming field parameter, based on the candidate RF shimming field parameter and each candidate sensitivity distribution matrix, the computer device determines a candidate SAR corresponding to each candidate sensitivity distribution matrix.

In operation 805, the computer device determines an object candidate position corresponding to the greatest candidate SAR as an initial local hotspot corresponding to the candidate RF shimming field parameter.

In operation 806, the computer device obtains target local hotspots by clustering the initial local hotspots.

In operation 807, the computer device determines a target set based on the target local hotspots and a target sensitivity distribution matrix corresponding to each target local hotspot.

In operation 808, the computer device determines a first SAR based on each candidate sensitivity distribution matrix.

In operation 809, the computer device determines a second SAR based on each target sensitivity distribution matrix.

In operation 810, the computer device determines a safety margin based on a difference between the first SAR and the second SAR.

In operation 811, the computer device obtains a target RF shimming field parameter.

In operation 812, the computer device determines an initial SAR corresponding to the target RF shimming field parameter based on the target RF shimming field parameter and the target set.

In operation 813, the computer device determines an SAR estimated value based on the safety margin and the initial SAR.

A detailed description of operations 801 to 813 can refer to the above embodiments and will not be repeated herein. Operations 801 to 810 may be performed at a preliminary offline stage, and operations 811 to 813 may be performed at a later use stage.

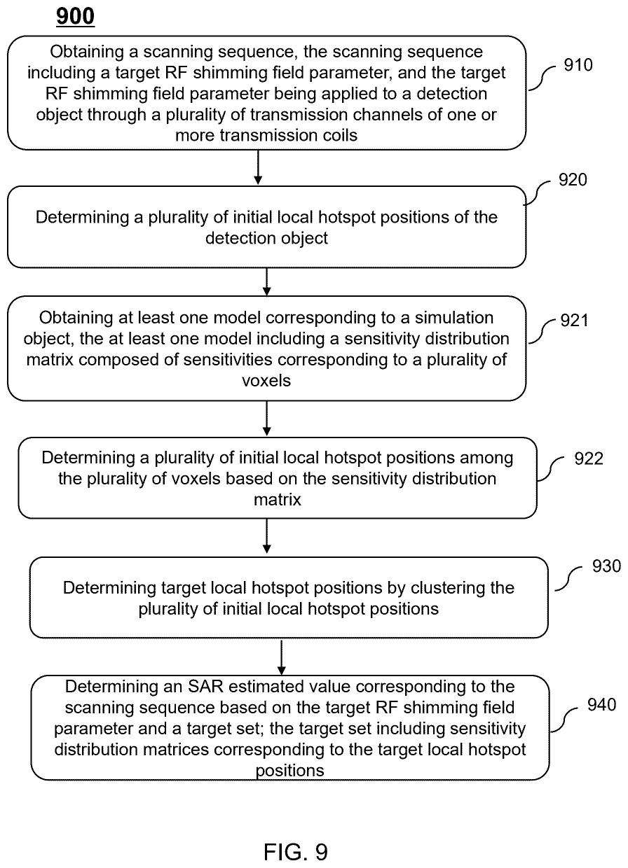

FIG. 9 is a flowchart illustrating an exemplary control method of MR scanning according to one embodiment of the present disclosure. In an exemplary embodiment, as illustrated in FIG. 9, a control method of MR scanning is provided. Taking the computer device shown in FIG. 1 as an example, the control method includes operations 910 to 940.

In operation 910, the computer device obtains a scanning sequence. The scanning sequence includes a target RF shimming field parameter, and the target RF shimming field parameter is applied to a detection object through a plurality of transmission channels of one or more transmission coils.

The scanning sequence refers to a sequence that is currently in actual use. The computer device may receive the scanning sequence sent by an MR system. A detailed description of the target RF shimming field parameter in the scanning sequence can refer to operation 530, and will not be repeated here.

In operation 920, the computer device determines a plurality of initial local hotspots of the detection object.

In some embodiments, the computer device determines the plurality of initial local hotspots of the detection object through operations 921 and 922 as follows.

In operation 921, the computer device obtains at least one model corresponding to a simulation object. The at least one model includes a sensitivity distribution matrix composed of sensitivities corresponding to a plurality of voxels.

The computer device may receive a model sent by other devices or may obtain a model from storage. In some embodiments, the computer device may further model the simulation object to obtain the at least one model corresponding to the simulation object.

The model of the simulation object includes the sensitivity distribution matrix composed of sensitivities corresponding to the plurality of voxels. Each voxel in the model is also an object candidate position, and each object candidate position corresponds to a candidate sensitivity distribution matrix, i.e., a sensitivity distribution matrix composed of sensitivities corresponding to the plurality of voxels.

In operation 922, the computer device determines a plurality of initial local hotspots among the plurality of voxels based on the sensitivity distribution matrix.

A detailed description of operation 922 can refer to the content related to determining the initial local hotspot, e.g., operation 520 and the related descriptions thereof.

In operation 930, the computer device determines target local hotspots by clustering the plurality of initial local hotspots.

A detailed description of operation 930 can refer to the content related to determining the target local hotspots, e.g., operation 520 and the related descriptions thereof.

In operation 930, the computer device determines an SAR estimated value corresponding to the scanning sequence based on the target RF shimming field parameter and a target set. The target set includes sensitivity distribution matrices corresponding to the target local hotspots.

The SAR estimated value corresponding to the scanning sequence is also an SAR estimated value corresponding to the target RF shimming field parameter in the scanning sequence. A detailed description of operation 940 can refer to operation 530 and the related descriptions thereof, and will not be repeated here.

In the control method of an MR scan, the scanning sequence includes the target RF shimming field parameter, and the target RF shimming field parameter is applied to the detection object through the plurality of transmission channels of the one or more transmission coils, due to the ability to acquire the scanning sequence and the at least one model corresponding to the simulation object, and the model includes the sensitivity distribution matrix composed of sensitivities corresponding to the plurality of voxels, it is possible to determine the plurality of initial local hotspots among the plurality of voxels based on the sensitivity distribution matrix, and further, obtain the target local hotspots by clustering the initial local hotspots. Besides, since the target local hotspots are hotspots obtained by clustering the initial local hotspots, a count of the target local hotspot is less than or equal to a count of the initial local hotspots. Furthermore, the target set includes the sensitivity distribution matrices corresponding to the target local hotspots, and based on the target RF shimming field parameter and the target set, the SAR estimated value corresponding to the scanning sequence can be determined quickly and efficiently.

In related techniques, the greatest value is generally predicted for each sequence as an RF pattern changes, and by default, the greatest value predicted for each sequence occurs at the same position. In fact, with the change of an RF shimming field pattern or the movement of the bed, a hotspot of the MR scanning may change, i.e., a local hotspot of a first sequence appears in position A, while a local hotspot of a second sequence appears at position B, and a local hotspot of a third sequence may again appear at position A. Thus, if a hotspot of each sequence is considered to be the same local hotspot, a local SAR over a period may be overestimated. Based on this, the present disclosure provides a method for superimposing an SAR in the following.

In an exemplary embodiment, the scanning sequence includes a first scanning sequence and a second scanning sequence performed sequentially, and the first scanning sequence and the second scanning sequence are performed in a preset time range, the target set includes a first set corresponding to the first scanning sequence and a second set corresponding to the second sequence. Operation 940 includes steps S41 to S43.

In operation S41, the computer device determines a third SAR based on the target RF shimming field parameter of the first scanning sequence and the first set.

In operation S42, the computer device determines a fourth SAR based on the target RF shimming field parameter of the second scanning sequence and the second set.

Therefore, if the scanning sequence includes the first scanning sequence and the second scanning sequence performed sequentially, and the first scanning sequence and the second scanning sequence are performed in a preset time range, then the computer device determines the third SAR based on the target RF shimming field parameter of the first scanning sequence and the first set, and then determines a fourth SAR based on the target RF shimming field parameter of the second scanning sequence and the second set.

A process for determining the third SAR and the fourth SAR may be referred to in operation 530. Taking the third SAR as an example, assuming that the first set includes a target sensitivity distribution matrix a through a target sensitivity distribution matrix c, then the computer device substitutes the target RF shimming field parameter of the first scanning sequence and the target sensitivity distribution matrix a in the first set into formula (1) to obtain SAR-a, substitutes the target RF shimming field parameter of the first scanning sequence and a target sensitivity distribution matrix b in the first set into formula (1) to obtain SAR-b, and substitutes the target RF shimming field parameter of the first scanning sequence and the target sensitivity distribution matrix c in the first set into formula (1) to obtain SAR-c. The computer device uses the greatest SAR-a as the third SAR, or uses SAR-a and SAR-b that are the top two in size as the third SAR. The fourth SAR is obtained similarly, which is not repeated here.

In operation S43, the computer device determines the SAR estimated value corresponding to the scanning sequence by superposing the third SAR and the fourth SAR.

In this embodiment, optionally, the computer device superposes the SAR at the same target local hotspot in the third SAR and the fourth SAR to determine the SAR estimated value corresponding to the scanning sequence. The target local hotspot corresponds to the target sensitivity distribution matrix in a one-to-one manner. That is, the computer device superimposes the SARs of the same target sensitivity distribution matrix in the third SAR and the fourth SAR to determine the SAR estimated value corresponding to the scanning sequence.

Continuing with the above example, assuming that the fourth SAR also includes the SAR-a corresponding to target sensitivity distribution matrix a, the computer device superimposes the SAR-a in the third SAR and the SAR-b in the fourth SAR to determine the SAR estimated value corresponding to the scanning sequence. The SAR estimated value corresponding to the scanning sequence may be a maximum value or an average value after superimposing the third SAR and the fourth SAR.

In the above embodiment, the scanning sequence includes the first scanning sequence and the second scanning sequence performed sequentially, and the first scanning sequence and the second scanning sequence are performed in the preset time range, the target set includes the first set corresponding to the first scanning sequence and the second set corresponding to the second sequence. As the third SAR is determined based on the target RF shimming field parameter of the first scanning sequence and the first set, and the fourth SAR is determined based on the target RF shimming field parameter of the second scanning sequence and the second set, and the third SAR and the fourth SAR are superposed, during a monitoring period, two sequences are scanned continuously. Although shimming field patterns of the two sequences are different, the hotspots of each sequence are not considered to be the same local hotspot, thereby more accurately determining the SAR estimated values corresponding to the scanning sequences.

In an exemplary embodiment, in a process of performing the scanning sequence, relative positions of the detection object and the transmission coil change; the above-mentioned operation 940 includes operations S51-S53.

In operation S51, before the relative positions change, the computer device determines a fifth SAR based on the target RF shimming field parameter and the target set.

In operation S52, after the relative positions change, the computer device determines a sixth SAR based on the target RF shimming field parameter and the target set.

A process for determining the fifth SAR and the sixth SAR may be referred to in operation 530, or to the above operations S41-S42, which is not repeated here.

In operation S53, the computer device determines the SAR estimated value corresponding to the scanning sequence by superposing the fifth SAR and the sixth SAR.

Furthermore, the computer device may superimpose the SAR at the same target local hotspot in the fifth SAR and the sixth SAR, that is, superimpose the SAR at the same target sensitivity distribution matrix in the fifth SAR and the sixth SAR, to determine the SAR estimated value corresponding to the scanning sequence. The SAR estimated value corresponding to the scanning sequence may be the maximum value or the average value after superimposing the fifth SAR and the sixth SAR.

A principle of S53 is similar to S43, which is not repeated here.

In the above embodiment, as the fifth SAR is determined based on the target RF shimming filed parameters and the target set before the relative position change, and the sixth SAR is determined based on the target RF shimming field parameter and the target set after the relative position change, although the same sequence is used, due to a movement of a bed or a body, the superposition of the fifth SAR and the sixth SAR more accurately determines the SAR estimated value corresponding to the scanning sequence.

It can be seen that in the present disclosure, since the selected I target sensitivity distribution matrices all have clear target local hotspots, each time a transmission mode changes or the relative positions of the detection object and the transmission coil changes, a local SAR value of each local hotspot and a duration of the SAR value may be accurately recorded. This allows the SAR of each hotspot within a period of time to be separately counted, thereby more accurately reflecting the changes in the local hotspots.

The following describes of the SAR monitoring process in an embodiment. The SAR monitoring may be performed according to S61-S66.

In operation S61, through a joint simulation of a coil modeling and a 3D electromagnetic field of a body model, the computer device obtains a series of body models, and electric field and human body tissue data of the body models at different positions relative to the transmission coil, and calculates the candidate sensitivity distribution matrix corresponding to the each object candidate position.

In operation S62, through an certain count of excitation of the amplitude and phase of a multi-channel transmission system, the computer device finds and clusters the initial local hotspots where the local SAR maximum value appears, and then selects a certain count of target local hotspots.

In operation S63, while selecting a certain count of local hotspots, the computer device gives an uncertainty of the calculation of selecting all positions and selecting a certain count of positions.

In operation S64, in a process of local SAR monitoring, the computer device needs to consider a necessary safety allowance caused by the uncertainty of the calculation of selecting all positions and selecting a certain count of positions.

In operation S65, in a process of local SAR monitoring of an MR system, according to the amplitude and the phase of the current scanning RF shimming field, the computer device calculates the local SAR superposed safety allowance of a certain count of selected local hotspots to perform the local SAR monitoring.

In operation S66, the computer device records the positions of the certain count of selected local hotspots and a local absorption of RF energy or the SAR value. The position information may be used for subsequent local SAR monitoring a plurality of scans.

In summary, in order to reduce a computational complexity of the local SAR monitoring under an RF shimming field condition, it is necessary to reduce the count of hotspots required for local SAR monitoring. The present disclosure proposes using the position clustering manner to select hotspots. A certain count of initial local hotspots are selected using the sufficient count of excitations, and these initial local hotspots are clustered to determine the target set. In this way, the need to store a Q matrix and calculate the local SAR at each position is reduced to only store and calculate the target sensitivity distribution matrix corresponding to the count of target local hotspots, thereby reducing the computational complexity of the local SAR monitoring.

Further, the target local hotspots obtained by clustering the initial local hotspots may be used for subsequent local SAR monitoring of multiple-scan. For example, the local SARs of a plurality of sequences within a standard time period are superimposed as belonging to the same target local hotspot, to more accurately reflect an actual local SAR situation at each point.

Furthermore, this embodiment provides a certain safety allowance to reduce the uncertainty caused by the reduction in the count of initial local hotspots, thereby improving the safety of the local SAR monitoring by hotspots clustered by position.

It may be seen that this embodiment proposes a local SAR calculation and management solution based on local hotspot clustering, which solves a problem of large local SAR calculation resources and a lack of local hotspot information caused by multi-channel transmitted RF shimming field parameter, which greatly saves a local SAR calculation time, and improves a local SAR calculation efficiency and accuracy in a multi-channel transmission MR system.

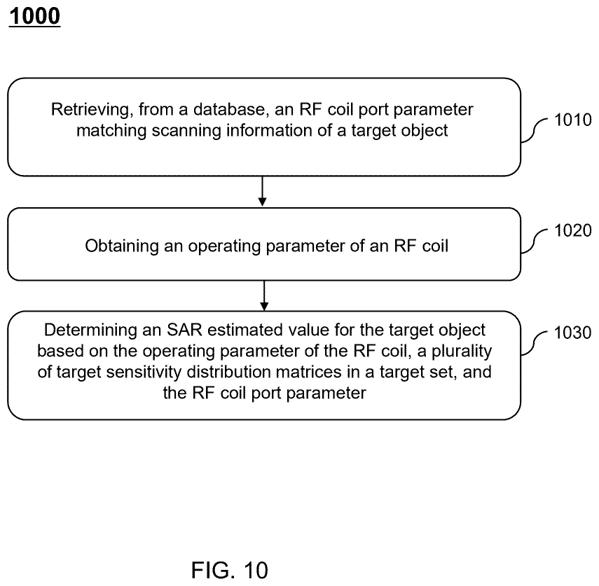

FIG. 10 is a flowchart illustrating an exemplary process for determining an SAR estimated value according to another embodiment of the present disclosure. In some embodiments, a process 1000 is executed by a computer device, and the process 1000 includes operations 1010 to 1030.

In operation 1010, the computer device retrieves, from a database, an RF coil port parameter matching scanning information of a target object.

In some embodiments, the database may include a relationship between the scanning information and the RF coil port parameter. For more information about the scanning information, please refer to FIG. 5 and the related descriptions thereof.

The RF coil port parameter refers to a parameter that characterizes the properties of an RF coil port in an MR device.

For example, the RF coil port parameter may include a scattering parameter, an impedance parameter, and a reflection parameter of the RF coil port. The scattering parameter may be used to describe the scattering characteristics of an RF signal at the port, the impedance parameters may be used to describe the input and output impedance of the RF signal at the port, and the reflection parameter may be used to characterize the reflection behavior of the RF signal at the port.

In some embodiments, the RF coil port parameter may quantify the reflection of RF signals, transmission efficiency, and impedance matching performance of the RF coil. The RF coil port parameter may directly reflect the extent of loss of RF signals by the RF coil. The greater the loss of RF signals by the RF coil, the lower the SAR in the human body.

In some embodiments, the computer device may further retrieve the database to determine the RF coil port parameter matching the scanning information of the target object.

In some embodiments, the database includes different types of scanning information and RF coil port parameters corresponding to each type of scanning information. The different types of scanning information may be obtained by simulating human models of different heights and weights, or may be scanning information of historical scanned target objects. The RF coil port parameter of the MR device may be obtained by simulating an electromagnetic field of the MR device, or may be a plurality of RF coil port parameters from historical scanning. The embodiments of the present disclosure do not limit the source of sensitivity distribution matrices and RF coil port parameters stored in the database.

In some embodiments, the computer device may construct the database based on the scanning information of the target object and the RF coil port parameter.

In the embodiments of the present disclosure, the computer device may match the scanning information of the target object with different types of scanning information in the database, and determine an RF shimming field parameter corresponding to successfully matched scanning information as the RF coil port parameter of the MR device.

In some embodiments, the database may include sensitivity distribution matrices of different body models and an RF coil port parameter corresponding to each body model.

The body model refers to a model used to characterize a physiological feature of a human body.

In some embodiments, the body model may be a physical model or a digital simulation model.

In some embodiments, different body models in the database have different physiological features. For example, different body models may have different heights and weights.

In some embodiments, the computer device may construct a body model based on physiological feature information of the target object.

For example, the computer device may determine a body model matching the target object based on an MRI image, height, weight, and age of the target object through a body model determination model. The body model determination model refers to a model used to construct a body model matching the target object. In some embodiments, the body model determination model may be a machine learning model. For example, the body model determination model may include any one or a combination of a CNN model or other custom models.

In some embodiments, an input of the body model determination model may include an MRI image and a physiological feature of the target object, and an output may include the body model matching the target object.

In some embodiments, the body model determination model may be obtained by training a large number of second training samples each of which is with a second training label. Each set of second training samples include sample MRI images and sample physiological features. The second training label corresponding to each set of second training samples is a body model of a target object corresponding to a set of second training samples.

The second training sample may be determined based on historical data. For example, the historical data may include a historical physiological feature of the target object from historical registration information and a historical MRI image obtained from historical scanning of the target object. For each set of second training samples, a manually constructed body model is determined as a second training label corresponding to each set of second training samples.

In some embodiments, the training of the body model determination model is similar to a training of a parameter prediction model. A detailed description of the training of the parameter prediction model can refer to the following description.

In some embodiments of the present disclosure, by constructing the database based on different body models, the distribution of an electromagnetic field generated by the RF coil in the human body can be more accurately simulated, making the data in the database more diverse and personalized. In this way, parameters can be quickly retrieved and applied during the actual scanning process, reducing the need for on-site calculations and improving scanning efficiency.

In some embodiments, the computer device may further construct the database based on scanning information of the body model and the RF coil port parameter. The embodiments of the present disclosure do not limit a method for constructing the database.

In some embodiments, the RF coil port parameter is related to a position of each coil channel relative to the corresponding body model.

For example, the farther the relative distance between the position of the coil channel and the position of the body model is, the smaller the reflection parameter, the smaller the scattering parameter, and the smaller the impedance parameter in the RF coil port parameter are.

In some embodiments of the present disclosure, the RF coil port parameter is related to the position of each coil channel relative to the corresponding body model, which can more accurately characterize the reflection of RF signals, transmission efficiency, and impedance matching degree of the RF coil when scanning different body models.

In some embodiments, the sensitivity distribution matrix and the RF coil port parameter for each body model are obtained from a three-dimensional electromagnetic field simulation of the body model through an RF coil model.

The RF coil model refers to a model used to simulate the sensitivity distribution matrix and the RF coil port parameter for the body model.

In some embodiments, the RF coil model may be constructed based on a plurality of sample RF coil port parameters.

The sample RF coil port parameter refers to a parameter used to construct the RF coil model. In some embodiments, the computer device may directly obtain the sample RF coil port parameter based on a configuration file of the MR device.

In some embodiments, the computer device may further estimate the sample RF coil port parameter based on the configuration file of the MR device. For example, the computer device may determine the sample RF coil port parameter using Maxwell's equations, based on factors such as the shape, dimensions, number of turns, and turn spacing of the RF coil.

For example, if the MR device includes eight RF coils and the RF coil model correspondingly includes eight RF coil ports, the computer device may directly read the configuration file to obtain a sample RF coil port parameter corresponding to each of the eight RF coil ports. Based on each sample RF coil port parameter and position information of an RF coil corresponding to each sample RF coil port parameter, the RF coil model may be constructed.

As another example, the database stores a plurality of RF coil port parameters. The computer device matches the configuration file of the MR device with the plurality of RF coil port parameters and determines a successfully matched RF coil port parameter as the RF coil port parameter of the MR device.

The three-dimensional electromagnetic field simulation refers to the simulation process of simulating the distribution and propagation of an electromagnetic field in three-dimensional space.

In some embodiments, the computer device may use the constructed RF coil model to perform a three-dimensional electromagnetic field simulation on body models and simulate an MR scanning process of the body models to obtain simulation results. Based on the simulation results, the computer device may determine the sensitivity distribution matrix and the RF coil port parameter of the MR device for each body model.

In some embodiments, after obtaining the sensitivity distribution matrices and the RF coil port parameters of the MR device for the body models, the computer device may store the sensitivity distribution matrices and the RF coil port parameters in the database.

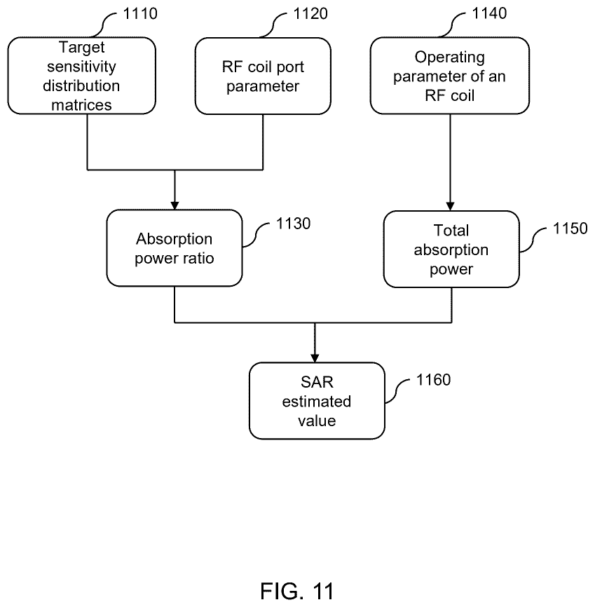

For example, the data stored in the database includes: the RF coil port parameters, head sensitivity distribution matrices, whole-body sensitivity distribution matrices, partial-body sensitivity distribution matrices, and local sensitivity distribution matrices. In some embodiments, the database may be a memory in the MR device. A detailed description of the local sensitivity distribution matrices and the whole-body sensitivity distribution matrices can refer to FIG. 11 and the related descriptions thereof.

It is understood that the computer device may further integrate the sensitivity distribution matrices and the RF coil port parameters of the MR device for the body models into a lookup table. The lookup table may include a relationship between the scanning information of the target object and the sensitivity distribution matrix, and a relationship between the scanning information of the target object and the RF coil port parameter. When it is necessary to retrieve the sensitivity distribution matrix and the RF coil port parameter of the MR device corresponding to the target object, the sensitivity distribution matrix and the RF coil port parameter matching the scanning information of the target object may be directly obtained from the lookup table.

In embodiments of the present disclosure, the RF coil model is used to perform the three-dimensional electromagnetic field simulation on the body models to obtain the sensitivity distribution matrices and the RF coil port parameters of the MR device for the body models; then, the database is constructed to simulate the MR scanning of the body models, so that the sensitivity distribution matrices and the RF coil port parameters for the body models can be accurately obtained, making the data in the database richer.

In some embodiments, the computer device may obtain image information of the target object, and retrieve the RF coil port parameter from the database based on the image information and the scanning information of the target object.

The image information refers to image information related to the scan of the target object. For example, the image information may be an MRI image, an RF field map from the scan, an anatomical structure image, etc.

In some embodiments, the computer device may obtain the image information of the target object through a prescan.

In some embodiments, the computer device may further obtain the image information of the target object based on historical scanning data of the target object.

The embodiments of the present disclosure do not limit a method for obtaining the image information.

In some embodiments, the database may further include a relationship between the RF coil port parameter and the image information, and a relationship between the RF coil port parameter and the scanning information of the target object. The computer device may construct a target vector based on the image information and the scanning information of the target object, construct a reference vector based on image information and scanning information stored in the database, determine a similarity between the target vector and the reference vector, and determine an RF coil port parameter corresponding to a reference vector with the highest similarity as the RF coil port parameter matching the target object. Methods for determining the similarity may include, but are not limited to, Euclidean distance, cosine similarity, or the like.

In some embodiments, the computer device may further directly generate a body model of the target object based on the image information, and derive the RF coil port parameter matching the target object based on the body model.

In some embodiments, the computer device may further determine a target sensitivity distribution matrix and the RF coil port parameter from the database based on the image information and the scanning information.

In some embodiments of the present disclosure, by generating a personalized model, parameters of the model can be directly retrieved in subsequent scans when the same target object is being scanned, thereby improving efficiency. For similar target objects, the personalized model may be shared through image feature clustering, thereby providing more accurate results.

In some embodiments, the computer device may further obtain an RF shimming field parameter of the target object during the prescan; and retrieve the sensitivity distribution matrix and the RF coil port parameter of the MR device for the target object from the database based on the physiological feature information of the target object and the RF shimming field parameter.

The RF shimming field parameter refers to the amplitude and phase of each coil channel of the MR device during the prescan of the target object. The RF shimming field parameter includes amplitude information and phase information of different coil channels. The amplitude information refers to the power or voltage amplitude of the coil channel, and the phase information refers to the phase angle of a signal within the coil channel.

The coil channel refers to a path or passage used to transmit, process, and receive RF signals. In some embodiments, the coil channel may include components such as a transmitter, a receiver, an antenna, a feeder, a filter, an amplifier, or the like.

In some embodiments, the computer device may determine the RF shimming field parameter based on an MRI image of the target object through a parameter determination model. The parameter determination model refers to a model used to determine the RF shimming field parameter. In some embodiments, the parameter determination model may be a machine learning model. For example, the parameter determination model may include any one or a combination of a GNN model or other custom models.

In some embodiments, an input of the parameter determination model may include the MRI image, and an output may include the RF shimming field parameter.

In some embodiments, the parameter determination model may be obtained by training a large number of third training samples each of which is with a third training label. Each set of third training samples may include sample MRI images, and a third training label corresponding to the set of third training samples is an RF shimming field parameter corresponding to the set of third training samples.

The third training sample may be determined based on historical data. For example, the historical data may be historical MRI images of the target object from the historical registration information. For each set of third training samples, a manually determined RF shimming field parameter is determined as the third training label corresponding to the set of third training samples.

In some embodiments, a training of the parameter determination model is similar to the training of the parameter prediction model. A detailed description of the training of the parameter prediction model can refer to the relevant description below.

In some embodiments, the RF shimming field parameter may also be determined based on the prescan of the target object.

In some embodiments, the computer device may obtain the amplitude information and the phase information of different coil channels during the prescan by pre-scanning the target object, and determine the amplitude information and the phase information of different coil channels as an RF shimming field parameter for subsequent formal scanning.

For example, a low-power prescan is performed on the target object. During the prescan, the amplitudes A₁, A₂, . . . , and Aₙ and phases ϕ₁, ϕ₂, . . . , and ϕₙ required for each coil channel are measured or calculated, and the amplitudes and phases of the coil channels are used as the RF shimming field parameter.

In some embodiments of the present disclosure, the RF shimming field parameter is determined based on the prescan of the target object, allowing for more precise adjustment of the transmission characteristics of the RF coil to suit the specific anatomical structure and electromagnetic properties of the target object. In this way, a clearer and more accurate image can be generated, thereby improving imaging quality while further ensuring that the MR device performs imaging within a safety threshold.

A detailed description of RF shimming field parameter can refer to FIG. 11 and the related descriptions thereof.

In some embodiments, if the target object has been pre-scanned and an RF shimming field parameter during the prescan is stored in a shimming field parameter database, based on identification information of the target object, the computer device may retrieve a relevant parameter identical to the identification information in the shimming field parameter database, and determine the relevant parameter identical to the identification information as the RF shimming field parameter for the target object. The shimming field parameter database refers to a database that stores shimming field parameters. In some embodiments, the shimming field parameter database may include the relationship between the identification information and the RF shimming field parameter. The identification information refers to information used to identify the target object. For example, the identification information may include the target object's ID, name, gender, etc. In some embodiments, the computer device may determine the identification information of the target object based on registration information of the target object.

In some embodiments, if the target object has not yet been pre-scanned, and the target object has been prepared for a prescan, the computer device may send a prescan instruction to the MR device. Upon receiving the prescan instruction, the MR device performs a prescan on the target object, and the computer device obtains the amplitude and phase of each coil channel during the prescan and determine the amplitude and phase of each coil channel as the RF shimming field parameter for subsequent scanning.

In some embodiments, the computer device may match the physiological feature information of the target object with a plurality of pieces of physiological feature information in the database, and determine successfully matched physiological feature information as candidate physiological feature information. The computer device may then match the RF shimming field parameter during the prescan with an RF shimming field parameter corresponding to the candidate physiological feature information, determine a similarity between the candidate physiological feature information and the RF shimming field parameter, and determine a sensitivity distribution matrix and an RF coil port parameter corresponding to a candidate physiological characteristic information with the greatest similarity as the sensitivity distribution matrix and the RF coil port parameter of the MR device for the target object.

In some embodiments of the present disclosure, the RF shimming field parameter for the target object during the prescan is obtained. Based on the physiological feature information of the target object and the RF shimming field parameter, the sensitivity distribution matrix, and the RF coil port parameter of the MR device for the target object are retrieved from the database, thereby accurately determining a transmission mode during an MR scan. Furthermore, based on the RF shimming field parameter and the physiological feature of the target object, the sensitivity distribution matrix and the RF coil port parameter for the target object can be accurately retrieved from the database.

In operation 1020, the computer device obtains an operating parameter of the RF coil.

The operating parameter of the RF coil refers to a real-time operating parameter of the RF coil during scanning.

In some embodiments, the operating parameter of the RF coil may include the RF shimming field parameter, a forward voltage, and a reverse voltage. The forward voltage refers to the voltage signal transmitted from the RF power amplifier (RFPA) to the RF coil in the forward direction, and the reverse voltage refers to the voltage signal reflected from the RF coil to the RFPA.

In some embodiments of the present disclosure, considering the RF shimming field parameter can improve the uniformity of an RF field in an imaging region, reduce image artifacts, and improve the overall image quality.

A detailed description of the operating parameter of the RF coil can refer to FIG. 11 and the related descriptions thereof.

In some embodiments, during a prescan stage, the computer device may obtain an actual operating parameter of the RF coil through the prescan and determine the actual operating parameter of the RF coil as the operating parameter of the RF coil.

The embodiments of the present disclosure do not limit a method for obtaining the operating parameter of the RF coil.

In operation 1030, the computer device determines an SAR estimated value for the target object based on the operating parameter of the RF coil, a plurality of target sensitivity distribution matrices in a target set, and the RF coil port parameter.

In some embodiments, the computer device may determine the SAR estimated value for the target object through a parameter prediction model based on the operating parameter of the RF coil, the plurality of target sensitivity distribution matrices in the target set, and the RF coil port parameter.

The parameter prediction model refers to a model used to predict an SAR estimated value for the target object. In some embodiments, the parameter prediction model may be a machine learning model. For example, the parameter prediction model may include any one or a combination of a CNN model or other custom models.

In some embodiments, an input of the parameter prediction model may include the operating parameter of the RF coil, the plurality of target sensitivity distribution matrices in the target set, and the RF coil port parameter, and an output of the parameter prediction model may include the SAR estimated value for the target object.

In some embodiments, the parameter prediction model may be obtained by training a large number of fourth training samples each of which is with a fourth training label. Each set of fourth training samples may include operating parameters of sample RF coils, sample target sensitivity distribution matrices of the target object, and sample RF coil port parameters. A fourth training label corresponding to the set of fourth training samples is an SAR estimated value for a target object corresponding to the set of fourth training samples.

The fourth training sample may be determined based on historical data. For example, the historical data may be historical RF coil operating parameters during historical scanning of the body model, historical target sensitivity distribution matrices, and historical RF coil port parameters. For each set of fourth training samples, the technician may measure an SAR estimated value for the target object, and a manually measured SAR estimated value for the target object is determined as the fourth training label corresponding to the set of fourth training samples.

In some embodiments, the computer device may train an initial parameter prediction model by conducting a plurality of iterations of the initial parameter prediction model based on a plurality of sets of fourth training samples each of which is with a fourth training label and terminate the training until a termination condition is satisfied, and obtain a trained parameter prediction model. At least one iteration includes: inputting one or more fourth training samples into the initial parameter prediction model, obtaining prediction outputs corresponding to the one or more fourth training samples from the initial parameter prediction model; substituting the prediction outputs corresponding to the one or more fourth training samples and fourth training labels corresponding to the one or more fourth training samples into a formula for a predefined loss function, calculating a value of the loss function; and iteratively updating a model parameter of the initial parameter prediction model according to the value of the loss function until the termination condition is satisfied, terminating the iteration, and obtaining the trained parameter prediction model. The iterative updating of the model parameter of the initial parameter prediction model may be carried out by a variety of methods, e.g., it may be carried out based on the gradient descent method. The termination condition may include the loss function converging or the number of iterations reaching an iteration count threshold, etc. The termination condition may further include the loss function converging, the number of iterations reaching a preset iteration count threshold, the value of the loss function being less than a preset function value threshold, etc.

In some embodiments, the computer device may determine the SAR estimated value for the target object based on a total absorption power of the MR device and an absorption power ratio of the target object. A detailed description of the determination of the SAR estimated value can be found in FIG. 11 and the related descriptions thereof.

In some embodiments of the present disclosure, the sensitivity distribution matrix and the RF coil port parameter enable accurate prediction of an SAR estimated value for the target object in the corresponding transmission mode. By monitoring the SAR estimated value for the target object, timely intervention can be carried out during the scanning process to prevent the adverse effects of SAR exceeding safety limits on the target object.

It should be noted that the foregoing description of the process 1000 is intended to be exemplary and illustrative only and does not limit the scope of application of the present disclosure. For a person skilled in the art, various corrections and changes can be made to the process 1000 under the guidance of the present disclosure. However, these corrections and changes remain within the scope of the present disclosure.

FIG. 11 is a schematic diagram illustrating an exemplary process for determining an SAR estimated value for a target object according to some embodiments of the present disclosure.

In some embodiments, a computer device may determine an absorption power ratio 1130 of a target object based on a plurality of target sensitivity distribution matrices 1110 in a target set and an RF coil port parameter 1120, determine a total absorption power 1150 of an MR device based on an operating parameter 1140 of an RF coil, and determine an SAR estimated value 1160 for the target object based on the total absorption power 1150 of the MR device and the absorption power ratio 1130 of the target object.

During the scanning process of the MR device, a portion of the absorption power is lost within the transmission coil itself, and another portion is dissipated into the surrounding space, and the remaining portion of the absorption power is then absorbed by the target object. The absorption power ratio of the target object refers to the ratio of the power absorbed by the target object to the total absorption power.

In some embodiments, the computer device may determine the absorption power ratio of the target object through a ratio prediction model based on the target sensitivity distribution matrices in the target set and the RF coil port parameter.

The ratio prediction modeling refers to a model used for determining the absorption power ratio of the target object. In some embodiments, the ratio prediction model may be a machine learning model. For example, the ratio prediction model may include any one or a combination of a CNN model, or other custom models.

In some embodiments, an input of the ratio prediction model includes the target sensitivity distribution matrices and the RF coil port parameter, and an output of the ratio prediction model includes the absorption power ratio of the target object.

In some embodiments, the ratio prediction model may be obtained by training a large number of fifth training samples each of which is with a fifth training label. Each set of fifth training samples may include sample target sensitivity distribution matrices and sample RF coil port parameters that match scanning information of the target object. A fifth training label corresponding to the set of fifth training samples is an absorption power ratio of a target object corresponding to the set of fifth training samples.

The fifth training sample may be determined based on historical data. For example, the historical data may be historical target sensitivity distribution matrices and historical RF coil port parameters during historical scanning of a body model. For each set of the fifth training samples, the technician may measure the absorption power of the target object to an RF signal and the total absorption power of the MR device, and a manually determined ratio of the absorption power of the target object to the RF signal to the total absorption power of the MR device is determined as the fifth training label corresponding to the set of fifth training samples.

In some embodiments, a training of the ratio prediction model is similar to the training of the parameter prediction model. A detailed description of the training of the parameter prediction model can refer to FIG. 10 and the related descriptions thereof.

In some embodiments, the computer device may further obtain physiological feature information of the target object and an RF shimming field parameter during a prescan, and determine the absorption power ratio of the target object based on the target sensitivity distribution matrices, the RF coil port parameter, a scanning portion of the target object, the physiological characteristic information of the target object, and the RF shimming field parameter.

It is to be understood that the computer device may retrieve, based on identification information of the target object, a relevant parameter identical to the identification information from a shimming field parameter database and determine the relevant parameter identical to the identification information as the RF shimming field parameter for the target object during the prescan. Or, the computer device may send a prescan instruction to the MR device, and upon receiving the prescan instruction, the MR device may perform a prescan on the target object, and the computer device may obtain the amplitude and phase of each coil channel during the prescan, and determine the amplitude and phase of each coil channel as the RF shimming field parameter during the prescan.

In some embodiments, the target sensitivity distribution matrix includes a local sensitivity distribution matrix and a whole-body sensitivity distribution matrix, and the computer device may obtain the whole-body sensitivity distribution matrix from the target sensitivity distribution matrix, and obtain a mass of the target object based on the physiological feature information of the target object. For example, the computer device may determine the absorption power ratio of the target object based on the whole-body sensitivity distribution matrix of the target object, the RF coil port parameter, the mass of the target object, and the RF shimming field parameter. In some embodiments, the computer device may determine the absorption power ratio of the target object by the formula (2):

$$SAR = \frac{\begin{matrix}{ω}^{H} \cdot whole - body sensitivity distribution matrix \cdot \\ mass of the target object\end{matrix}}{{ω}^{H} \cdot ω - {( S 0 \cdot ω )}^{H} \cdot ( S 0 \cdot ω )} \qquad ( 2 )$$

where, ω denotes the RF shimming field parameter, ω^{H} denotes the ω-Hermitian transpose, the whole-body sensitivity distribution matrix refers to a matrix representing the absorption characteristics of the entire human body tissue to RF energy, and S0 denotes a scattering parameter matrix of a multi-port RF coil.

In some embodiments, ω denotes the RF shimming field parameter after normalization, and an RF shimming field parameter of each coil channel may be normalized with respect to an RF shimming field parameter of a first coil channel, and the RF shimming field parameter is denoted as

$${ω}_{1} = 1 ; {ω}_{2} = \frac{{A}_{2}}{{A}_{1}} {e}^{j ( {ϕ}_{2} - {ϕ}_{1} )} ; … … ; {ω}_{n} = \frac{{A}_{n}}{{A}_{1}} {e}^{j ( {ϕ}_{n} - {ϕ}_{1} )} ,$$

where ϕₙ denotes the phase of a transmission signal within each transmission channel.

In some embodiments of the present disclosure, the physiological feature information of the target object and the RF shimming field parameter during the prescan are obtained, and the absorption power ratio of the target object is determined based on the target sensitivity distribution matrices, the RF coil port parameter, the scanning portion of the target object, the physiological feature information of the target object, and the RF shimming field parameter. By introducing the RF coil port parameter (such as the scattering parameter matrix), the RF power loss after entering the RF coil can be quantified, thereby correcting the impact of RF coil port characteristics on the determination of the absorption power ratio.

In some embodiments, the computer device may further determine the absorption power ratio of the target object based on the plurality of target sensitivity distribution matrices in the target set, the RF coil port parameter, and the RF shimming field parameter.

For example, the computer device may determine the absorption power ratio of the target object by the formulas (4), (5), (6), and (7) based on the target sensitivity distribution matrices in the target set, the RF coil port parameter, and the RF shimming field parameter.

A detailed description of the formulas (4), (5), (6), and (7) can refer to the relevant descriptions below.

In some embodiments of the present disclosure, determining the absorption power ratio of the target object based on the target sensitivity distribution matrices, the RF coil port parameter, and the RF shimming field parameter can improve the accuracy of the absorption power ratio of the target object.

The total absorption power refers to the sum of the power transmission by the RF coil that is absorbed by the human body or device.

In some embodiments, when performing the prescan, the computer device may determine the transmission power based on the voltage measurement value of the RF coil, and determine the total absorption power of the MR device based on the transmission power and the power reflected to the source. The voltage measurement value refers to the voltage amplitude of the RF coil. The transmission power refers to the power of the RF signal that the RF coil transmits to the body model or the target object during operation. The power reflected to the source power refers to the power of the portion of the RF signal transmitted from the RF coil that is reflected to the target (e.g., the body model) because it is not effectively transmitted to the target.

In some embodiments, the operating parameter of the RF coil further includes a forward voltage and a reverse voltage of each coil channel.

The forward voltage refers to the voltage signal transmitted from the RFPA forward to the RF coil.

The reverse voltage refers to a voltage signal that is reflected from the RF coil to the RFPA.

In some embodiments, the computer device may measure the forward voltage and the reverse voltage of each coil channel in the MR device, and determine the total absorption power of the MR device based on the forward voltage and the reverse voltage of each coil channel.

In some embodiments, the computer device may measure the forward voltage and the reverse voltage of each coil channel in the MR device, and determine a total absorption power of a plurality of coil channels in the MR device based on the forward voltage and the reverse voltage of each coil channel.

In some embodiments, the computer device may further determine the sum of the squared differences of the forward voltages and the reverse voltages of the plurality of coil channels in the MR device, and determine a ratio of the sum of the squared differences to the impedance of the coil channels as the total absorption power of the plurality of coil channels.

In some embodiments, the computer device may determine the total absorption power of the MR device by the formula (3) based on the forward voltages and the reverse voltages of the coil channels in the MR device:

$$Ptotal = {\sum }^{n} ( {\vert {UF}_{i} \vert}^{2} - {\vert {UR}_{i} \vert}^{2} ) / Z 0 \qquad ( 3 )$$

where, Ptotal denotes the total absorption power; Z0 denotes the characteristic impedance of the RF coil, and in general, Z0=50 ohm, i.e., the impedance of the RF coil; UFi denotes a forward voltage of an i-th RF coil; and URi denotes a reverse voltage of the i-th RF coil.

In some embodiments of the present disclosure, the forward voltage and the reverse voltage of each coil channel in the MR device are measured, and, based on the forward voltage and the reverse voltage of each coil channel, the total absorption power of the plurality of coil channels in the MR device is determined. Since the forward voltage and the reverse voltage herein are obtained through measurement, the total absorption power of the plurality of coil channels in the MR device can be accurately determined based on the measured forward voltage and the reverse voltage.

FIG. 3 is a schematic diagram illustrating principles of a plurality of exemplary RF coils in an MR device according to some embodiments of the present disclosure.

In some embodiments, an RF transmission signal of each channel is amplified by an RFPA. The signal is then passed through a directional coupler to acquire a forward voltage (UFₙ) and a reverse voltage (URₙ), and subsequently fed into the RF coil to excite an MR signal, then the MR signal is acquired and the acquired signal is converted into a digital signal via analog-to-digital (A/D) conversion, and after data processing, power monitoring or SAR monitoring is performed. A multi-channel transmission system provides more free adjustment variables for an ultra-high-field MR system, i.e., the transmitted complex signals of each channel, A₁(ϕ₁), A₂(ϕ₂), . . . , and Aₙ(ϕₙ), control RF fields of coil units of each channel to be combined into a more homogeneous synthesized RF field in a target imaging region, where A₁, A₂, . . . , and Aₙ denote the amplitude of the transmission signals within each channel, and ϕ₁, ϕ₂, . . . , and ϕₙ denote the phase of the transmission signals within each channel, respectively.

The acquisition signal refers to an MR signal received by the RF coil and generated by the target object after RF excitation. The digital signal is the acquisition signal obtained after the A/D conversion. The multi-channel transmission system refers to a component in the MR device that controls the simultaneous transmission of RF signals from a plurality of coil channels. The ultra-high-field MR system refers to an MR system that uses high magnetic field strengths (typically greater than 3 Tesla). The transmitted complex signal refers to an RF signal that includes both the amplitude and phase. The RF field refers to the magnetic field generated by the RF coil. The transmission signal refers to the RF signal that is amplified by the power amplifier and transmitted through the RF coil.

In some embodiments of the present disclosure, determining the total absorption power based on the forward voltage and the reverse voltage of each coil channel can effectively avoid the error in estimating the total absorption power.

In some embodiments, the SAR estimated value for the target object includes a whole-body SAR, and the computer device may determine a product of the total absorption power of the MR device and the absorption power ratio of the target object, and determine a ratio of the product to the mass of the target object as the whole-body SAR for the target object.

In some embodiments, the computer device may perform a verification on the SAR estimated value for the target object, and in response to determining that the SAR estimated value for the target object passes the verification, MR scanning on the target object is performed by the MR device.

In some embodiments, the computer device may compare the SAR estimated value for the target object with a predetermined threshold value, and in response to determining that the SAR estimated value for the target object is greater than or equal to the predetermined threshold value, it indicates that the SAR estimated value for the target object is large and the target object is unsuitable for the MR scan, i.e., the verification fails. In response to determining that the SAR estimated value for the target object is less than the preset threshold value, it indicates that the SAR estimated value for the target object is small and the MR scanning can be carried out, i.e., the verification is passed.

In some embodiments, in the case where the SAR estimated value for the target object passes the verification, the computer device may send a scan instruction to the MR device, and upon receiving the scan instruction, the MR device performs MR scanning on the target object based on the scan instruction.

In some embodiments of the present disclosure, the verification on the SAR estimated value for the target object is performed. If the verification on the SAR estimated value for the target object is passed, the MR scanning is performed on the target object by the MR device, which enables analysis of the SAR estimated value for the target object, thereby accurately determining whether the target object can undergo an MR scanning and improving the safety during the MR scanning process.

In some embodiments, in the process of scanning the target object using the MR device, the computer device may further acquire measurement voltage values of a plurality of coil channels, and determine a current SAR estimated value for the target object based on the measurement voltage values of the plurality of coil channels, and in response to determining that a verification on the current SAR estimated value fails, the MR device is controlled to stop scanning.

In some embodiments, each RF coil in the MR device transmits an RF field in the process of scanning the target object, in which case a forward voltage and a reverse voltage of a bidirectional coupler of each RF coil may be generated. The computer device may measure the forward voltage and the reverse voltage of each RF coil using a voltage detection device to obtain the voltage measurement values of the plurality of coil channels.

In some embodiments, when the voltage measurement values of the plurality of RF coils are obtained, the computer device may determine the total absorption power of the plurality of coil channels in the MR device by the formula (3) and determine the current SAR estimated value for the target object based on the total absorption power, the mass of the target object, and sensitivity distribution matrices.

In some embodiments, the computer device may compare the current SAR estimated value with a preset threshold value, and in response to determining the current SAR estimated value is greater than or equal to the preset threshold value, it indicates that the verification on the current estimated value SAR fails; in response to determining the current SAR estimated value is less than the preset threshold value, it indicates that the verification on the current SAR estimated value is passed. In the case where the verification fails, it indicates that it is not possible to continue the subsequent MR scanning process, and at this time, the computer device may control the MR device to stop scanning.

In some embodiments of the present disclosure, in the process of scanning the target object using the MR device, the voltage measurement values of the plurality of coil channels are obtained; based on the voltage measurement values of the plurality of coil channels, the current SAR estimated value for the target object is determined; and in response to determining that the verification on the current SAR estimated value fails, the MR device is controlled to stop scanning. The method measures the voltage during the scanning process and can accurately determine the current SAR estimated value based on the voltage measurement value. Then, by means of the verification, an abnormality can be detected in time, and the MR device can be controlled to stop scanning, which ensures the safety of the scanning process using the MR device.

In some embodiments of the present disclosure, determining the whole-body SAR based on the product of the total absorption power and the absorption power ratio of the target object can improve the accuracy of the whole-body SAR.

In some embodiments, the SAR estimated value for the target object further includes a local SAR. The computer device may obtain the local sensitivity distribution matrix and the whole-body sensitivity distribution matrix of the target object, and determine the local SAR for the target object based on the whole-body SAR, the local sensitivity distribution matrix, and the whole-body sensitivity distribution matrix.

The local SAR refers to an SAR for a portion of body tissues of the target object.

The local sensitivity distribution matrix refers to a sensitivity distribution matrix of a portion of body tissues of the target object.

In some embodiments, the computer device may determine the local sensitivity distribution matrix through the parameter prediction model based on a physiological feature (e.g., mass) of a portion of body tissues of the target object.

In some embodiments, the computer device may obtain a ratio of the local sensitivity distribution matrix of the target object to the whole-body sensitivity distribution matrix, and determine a product of the ratio and the whole-body SAR for the target object as the local SAR for the target object.

In some embodiments, the computer device may determine the local SAR based on the whole-body SAR, the local sensitivity distribution matrix, the whole-body sensitivity distribution matrix, and the RF shimming field parameter. For example, when a scan of the target object is a local scan, the local SAR may be determined by the formula (4):

$$Local SAR = whole bopdy SAR \frac{{ω}^{H} \cdot local sensitivity distribution matrix \cdot ω}{{ω}^{H} \cdot whole - body sensitivity distribution matrix \cdot ω} \qquad ( 4 )$$

where, ω denotes the RF shimming field parameter after normalization, and an RF shimming field parameter of each coil channel may be normalized relative to an RF shimming field parameter of a first coil channel, and the RF shimming field parameter is denoted as

$${ω}_{1} = 1 ; {ω}_{2} = \frac{{A}_{2}}{{A}_{1}} {e}^{j ( {ϕ}_{2} - {ϕ}_{1} )} ; … … ; {ω}_{n} = \frac{{A}_{n}}{{A}_{1}} {e}^{j ( {ϕ}_{n} - {ϕ}_{1} )} ,$$

where ϕₙ denotes the phase of the transmission signals within each channel.

As ω differs in each prescan, it cannot be eliminated from the formula (4).

Further, a ratio of the local SAR to the whole-body SAR may be calculated from a series of different information (e.g., height, weight) of the target object and a position of the target object relative to the coil channel in accordance with the fitting data.

In some embodiments, when the ratio of the local sensitivity distribution matrix to the whole-body sensitivity distribution matrix is obtained, the computer device may multiply the ratio by the whole-body SAR for the target object and determine the product as the local SAR for the target object.

In some embodiments of the present disclosure, the ratio of the local sensitivity distribution matrix of the target object to the whole-body sensitivity distribution matrix is obtained; and the product of the ratio and the whole-body SAR for the target object is determined as the local SAR for the target object. The method can accurately calculate the local SAR for the target object by the formula (4) based on the whole-body SAR and the sensitivity distribution matrices.

The whole-body sensitivity distribution matrix refers to a sensitivity distribution matrix of the whole body of the target object.

In some embodiments, the computer device may determine the whole-body sensitivity distribution matrix based on the physiological feature (e.g., weight) of the entire body of the target object through the parameter prediction model.

In some embodiments, the computer device may further obtain a ratio of the absorption power ratio of the target object to the mass of the target object, and determine a product of the ratio and the total absorption power as the whole-body SAR for the target object.

In some embodiments, the computer device may determine the whole-body SAR based on the total absorption power, the absorption power ratio of the target object, and the mass of the target object. For example, the whole-body SAR may be determined by the formula (5):

$$whole - body SAR = \frac{Ptotal absorption power ratio}{mass of target object} \qquad ( 5 )$$

where, Ptotal denotes the total absorption power.

A more detailed description of the parameter prediction model can be found in FIG. 10 and the related descriptions thereof.

In some embodiments, the computer device may obtain a ratio of a head sensitivity distribution matrix of the target object to the whole-body sensitivity distribution matrix of the target object, and determine a product of the ratio and the whole-body SAR for the target object as a head SAR for the target object.

In some embodiments, the computer device may determine the head SAR based on the whole-body SAR, the head sensitivity distribution matrix, the whole-body sensitivity distribution matrix, and the RF shimming field parameter. For example, when the local scan of the target object is a head scan, the head SAR may be determined by the formula (6):

$$heah SAR = whole - body SAR \frac{{ω}^{H} \cdot head sensitivity distribution matrix \cdot ω}{{ω}^{H} \cdot whole - body sensitivity distribution matrix \cdot ω} \qquad ( 6 )$$

Further, the computer device may determine a ratio of the head SAR to the whole-body SAR based on physiological feature information (e.g., height, weight) of the target object and the position of the target object relative to the coil channel in accordance with the fitting data.

In some embodiments of the present disclosure, the ratio of the head sensitivity distribution matrix of the target object to the whole-body sensitivity distribution matrix of the target object is obtained, and the product of the ratio and the whole-body SAR for the target object is determined as the head SAR for the target object. The method can accurately calculate the head SAR for the target object by a formula for calculating the head SAR based on the whole-body SAR and the sensitivity distribution matrices.

In some embodiments, the computer device may further obtain a ratio of a partial-body sensitivity distribution matrix of the target object to the whole-body sensitivity distribution matrix of the target object, and determine a product of the ratio and the whole-body SAR for the target object as a partial-body SAR for the target object.

In some embodiments, the computer device may determine the partial-body SAR based on the whole-body SAR, the partial-body sensitivity distribution matrix, the whole-body sensitivity distribution matrix, and the RF shimming field parameter. For example, when a local scan of the target object is a partial-body scan, the partial-body SAR may be determined by the formula (7):

$$partial - body SAR = whole - body SAR \frac{{ω}^{H} \cdot partial - body sensitivity distribution matrix \cdot ω}{{ω}^{H} \cdot whole - body sensitivity distribution matrix \cdot ω} \qquad ( 7 )$$

In some embodiments of the present disclosure, the ratio of the partial-body sensitivity distribution matrix of the target object to the whole-body sensitivity distribution matrix of the target object is obtained, and the product of the ratio and the whole-body SAR for the target object is determined as the partial-body SAR for the target object. The method can accurately determine the partial-body SAR for the target object by a formula for calculating the partial-body SAR based on the whole-body SAR and the sensitivity distribution matrices.

In some embodiments, the computer device may further manage an MR scanning process of the target object based on the SAR estimated value for the target object.

For example, after obtaining the SAR estimated value for the target object, in one case, the computer device may analyze the SAR estimated value for the target object to determine whether a scanning condition is satisfied (e.g., whether a local absorption power ratio is not greater than a preset value). A subsequent MR scanning is performed on the target object if the scanning condition is satisfied. In the case where the scanning condition is not satisfied, the SAR estimated value for the target object needs to be redetermined. On the other hand, the computer device may determine the SAR estimated value for the target object during the scanning process based on the measured forward voltage and reverse voltage. Based on the SAR estimated value, the computer device may determine whether the target object satisfies the scanning condition during the scanning process. If it is determined that the SAR estimated value for the target object during the scanning process does not satisfy the scanning condition, the MR scanning is stopped.

In some embodiments of the present disclosure, the MR scanning process of the target object is managed based on the SAR estimated value for the target object. Since the total absorption power is calculated based on the measured voltage, the SAR estimated value for the target object determined based on the total absorption power can also be more accurate, which allows more precise management of the MR scanning process of the target object.

In some embodiments of the present disclosure, the ratio of the local SAR to the whole-body SAR may be determined based on physiological feature information (e.g., height, weight) of the target object and the position of the target object relative to the coil channel.

In some embodiments of the present disclosure, the effect of physiological features and scanning portions of different target objects on the absorption power ratio can be corrected by real-time matching between the sensitivity distribution matrix and the RF shimming field parameter.

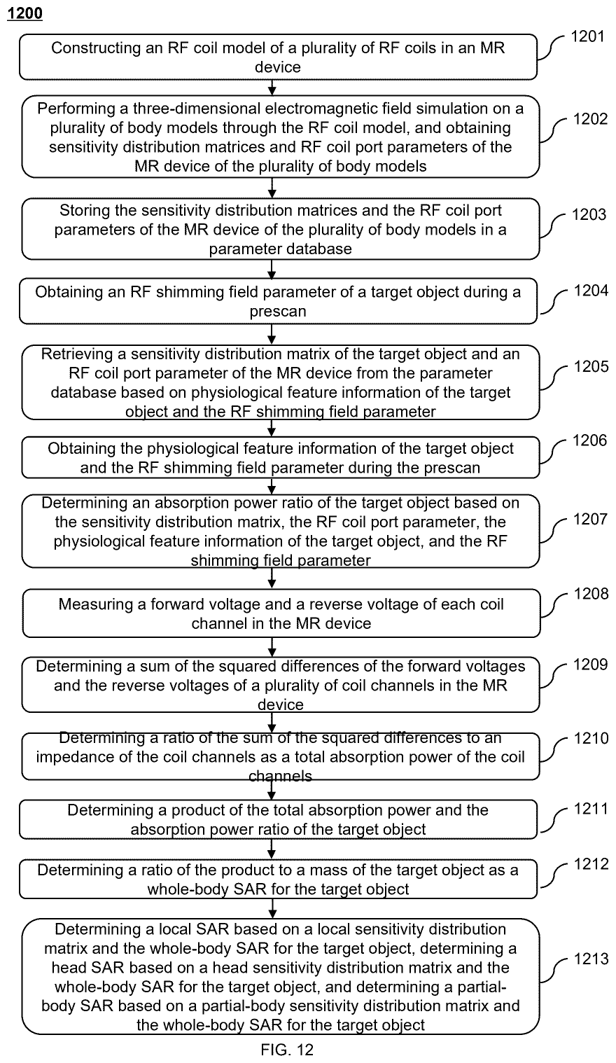

FIG. 12 is a flowchart illustrating an exemplary process for determining an SAR estimated value according to another embodiment of the present disclosure. In some embodiments, a process 1200 is performed by a computer device. The process 1200 includes operations 1201 to 1213.

In operation 1201, the computer device constructs an RF coil model of a plurality of RF coils in an MR device.

In operation 1202, the computer device performs a three-dimensional electromagnetic field simulation on a plurality of body models through the RF coil model, and obtains sensitivity distribution matrices and RF coil port parameters of the MR device of the plurality of body models.

In operation 1203, the computer device stores the sensitivity distribution matrices and the RF coil port parameters of the MR device of the plurality of body models in a parameter database.

In operation 1204, the computer device obtains an RF shimming field parameter of a target object during a prescan.

In operation 1205, the computer device retrieves a sensitivity distribution matrix of the target object and an RF coil port parameter of the MR device from the parameter database based on physiological feature information of the target object and the RF shimming field parameter.

In operation 1206, the computer device obtains the physiological feature information of the target object and the RF shimming field parameter during the prescan.

In operation 1207, the computer device determines an absorption power ratio of the target object based on the sensitivity distribution matrix, the RF coil port parameter, the physiological feature information of the target object, and the RF shimming field parameter.

In operation 1208, the computer device measures a forward voltage and a reverse voltage of each coil channel in the MR device.

In operation 1209, the computer device determines a sum of the squared differences of the forward voltages and the reverse voltages of a plurality of coil channels in the MR device.

In operation 1210, the computer device determines a ratio of the sum of the squared differences to an impedance of the coil channels as a total absorption power of the coil channels.

In operation 1211, the computer device determines a product of the total absorption power and the absorption power ratio of the target object.

In operation 1212, the computer device determines a ratio of the product to a mass of the target object as a whole-body SAR for the target object.

In operation 1213, the computer device determines a local SAR based on a local sensitivity distribution matrix and the whole-body SAR for the target object, determines a head SAR based on a head sensitivity distribution matrix and the whole-body SAR for the target object, and determines a partial-body SAR based on a partial-body sensitivity distribution matrix and the whole-body SAR for the target object.

More about the parameters in process 1200 can refer to FIG. 10, FIG. 11, and the related descriptions thereof.

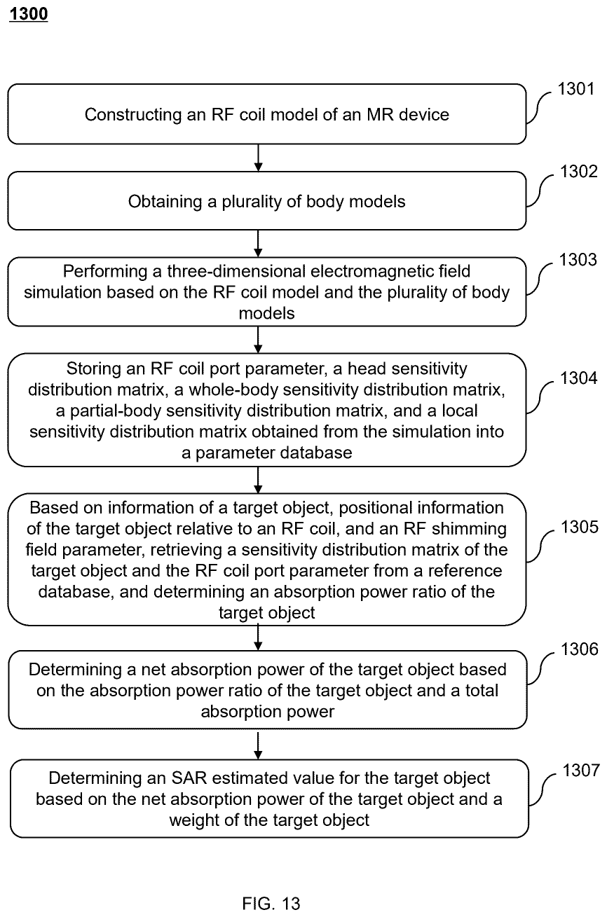

FIG. 13 is a flowchart illustrating an exemplary process for determining an SAR estimated value according to another embodiment of the present disclosure. In some embodiments, a process 1300 is performed by a computer device. The process 1300 includes operations 1301 to 1307.

In operation 1301, the computer device constructs an RF coil model of an MR device.

In operation 1302, the computer device obtains a plurality of body models.

In operation 1303, the computer device performs a three-dimensional electromagnetic field simulation based on the RF coil model and the plurality of body models.

In operation 1304: the computer device stores an RF coil port parameter, a head sensitivity distribution matrix, a whole-body sensitivity distribution matrix, a partial-body sensitivity distribution matrix, and a local sensitivity distribution matrix obtained from the simulation into a parameter database.

In operation 1305, based on information of a target object, position information of the target object relative to an RF coil, and an RF shimming field parameter, the computer device retrieves a sensitivity distribution matrix of the target object and the RF coil port parameter from a reference database, and determines an absorption power ratio of the target object.

In operation 1306, the computer device determines a net absorption power of the target object based on the absorption power ratio of the target object and a total absorption power.

In operation 1307, the computer device determines an SAR estimated value for the target object based on the net absorption power of the target object and a weight of the target object.

More about the parameters in the process 1300 can refer to FIG. 10, FIG. 11, and the related descriptions thereof.

It will be appreciated that although the individual operations in process 1200 and process 1300 as related to the embodiments as described above are shown in sequence as indicated by the arrows, the operations are not necessarily executed in sequence as indicated by the arrows. Unless explicitly stated herein, there is no strict order limitation on the execution of these operations, and the operations may be executed in other orders. Moreover, at least a portion of the operations in the flowchart involved in embodiments such as those described above may include a plurality of operations or a plurality of phases, which are not necessarily executed to completion at the same moment, but may be different moments, and the order in which these operations or phases are executed is not necessarily sequential, but may be executed in turn or alternately with other operations or at least a portion of operations or phases in other operations.

One or more embodiments of the present disclosure provides a computer device. The computer device includes a memory stored with a computer program and a processor. The processor performs the computer program by the following operations.

In operation S71, the computer device obtains a initial RF shimming field parameter.

A process for obtaining the initial RF shimming field parameter may be referred to in operation S11, which is not repeated here.

In operation S72, by processing the initial RF shimming field parameter, the computer device obtains each object candidate position in a simulation object and each candidate RF shimming field parameter corresponding to the each object candidate position.A process for determining the each candidate RF shimming field parameter may be referred to in operation S12, which is not repeated here.

In operation S73, the computer device determines an initial local hotspot of a detection object corresponding to the each candidate RF shimming field parameter.

A process for determining the initial local hotspot may be referred to in operation 520, which is not repeated here.

In operation S74, the computer device obtains a plurality of target sensitivity distribution matrices corresponding to a plurality of target local hotspots by performing a lookup in the table, the plurality of target local hotspots in the table being obtained by clustering the plurality of initial local hotspots.

In some embodiments, the computer device obtains the plurality of target local hotspots by clustering based on at least one of a position, a size and a feature value of each of the plurality of initial local hotspots.

A process for determining the at least one of a position, a size and a feature value of each of the plurality of initial local hotspots may be referred to in operation 520, which is not repeated here.

In operation S75, the computer device determines a safety allowance, and obtains a target RF shimming field parameter.

In some embodiments, the computer device determines object candidate positions of a simulation object and a candidate sensitivity distribution matrix corresponding to each object candidate position; and determines the safety allowance based on the plurality of candidate sensitivity distribution matrices and plurality of target sensitivity distribution matrices.

In operation S76, the computer device determines the initial SAR corresponding to the target RF shimming field parameter based on the target RF shimming field parameter and the target positions.

A process for determining the safety allowance, obtaining the target RF shimming field parameter, and actively determining the initial SAR may be referred to in descriptions in FIGS. 7 and 8, which is not repeated here.

In operation S77, the computer device determines the SAR evaluated value based on the safety allowance and the initial SAR.

A process for determining the SAR evaluated value may be referred to in operation 530 and related descriptions in FIG. 8, which is not repeated here.

The basic concepts have been described above, and it will be apparent to those skilled in the art that the foregoing detailed disclosure serves only as an example and does not constitute a limitation of the present disclosure. While not expressly stated herein, a person skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Also, the present specification uses specific words to describe the exemplary embodiments of the present disclosure. The words such as “one embodiment”, “an embodiment”, and/or “some embodiments” means a feature, structure, or characteristic associated with at least one embodiment of the present disclosure. Accordingly, it should be emphasized and noted that “one embodiment” or “an embodiment” or “an alternative embodiment” in different places in the present disclosure do not necessarily refer to the same embodiment. In addition, certain features, structures, or characteristics in one or more embodiments of the present specification may be suitably combined.

In addition, the order of processing elements and sequences, the use of numerical letters, or the use of other names described herein are not intended to qualify the order of the processes and methods of the present disclosure, unless expressly stated in the claims. While some embodiments of the invention that are currently considered useful are discussed in the foregoing disclosure by way of various examples, it should be appreciated that such details serve only illustrative purposes, and that additional claims are not limited to the disclosed embodiments, rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be noted that in order to simplify the presentation of the present disclosure, and thereby aid in the understanding of one or more embodiments of the invention, the foregoing descriptions of embodiments of the present disclosure sometimes combine a variety of features into a single embodiment, accompanying drawings, or the description thereof. description thereof. However, this method of disclosure does not imply that the objects of the present disclosure require more features than those mentioned in the claims. Rather, claimed object matter may lie in less than all features of a single foregoing disclosed embodiment.

Numbers describing the number of compositions, attributes are used in some embodiments, and it should be understood that such numbers used for the description of embodiments use the modifiers “about”, “approximately”, or “generally”. Unless otherwise noted, the terms “about,” “approximately,” or “generally” indicates that a ±20% variation in the stated number is allowed. Correspondingly, in some embodiments, the numerical parameters used in the present disclosure and claims are approximations, which can change depending on the desired characteristics of individual embodiments. In some embodiments, the numerical parameters should consider the specified number of valid digits and use a general digit retention method. While the numerical domains and parameters used to confirm the breadth of their ranges in some embodiments of the present disclosure are approximations, in specific embodiments, such values are set to be as precise as possible within a feasible range.

For each of the patents, patent applications, patent application disclosures, and other materials, such as articles, books, specification sheets, publications, documents, and the like, cited in the present disclosure, the entire contents of which are hereby incorporated herein by reference. Application history documents that are inconsistent with or conflict with the contents of the present disclosure are excluded, as are documents (currently or hereafter appended to the present disclosure) that limit the broadest scope of the claims of the present disclosure. It should be noted that to the extent that there is an inconsistency or conflict between the descriptions, definitions, and/or use of terms in the materials appurtenant to the present disclosure and those set forth herein, the descriptions, definitions, and/or use of terms in the present disclosure shall prevail.

Finally, it should be understood that the embodiments described in the present disclosure are used only to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A method for determining a specific absorption rate (SAR) comprising:
obtaining scanning information of a target object, the scanning information including a physiological feature of the target object and position information of a radiofrequency (RF) coil in a magnetic resonance (MR) device;
obtaining a target set matching the scanning information of the target object, the target set including a plurality of target sensitivity distribution matrices corresponding to a first count of target local hotspots, wherein the first count of target local hotspots are determined based on a second count of initial local hotspots on a body model, and the second count is greater than the first count; and
determining an SAR estimated value for the target object based on a target RF shimming field parameter of an RF coil and the target set.

2. The method of claim 1, wherein the determining an SAR estimated value for the target object based on a target RF shimming field parameter of an RF coil and the target set includes:
determining an initial SAR corresponding to the target RF shimming field parameter based on the target RF shimming field parameter and the target set; and
determining the SAR estimated value based on a safety margin and the initial SAR.

3. The method of claim 2, wherein the determining an initial SAR corresponding to the target RF shimming field parameter based on the target R F shimming field parameter and the target set comprises:
for each of the target local hotspots, calculating an SAR for the target local hotspot based on the corresponding target sensitivity distribution matrix; and
selecting a greatest value among all the specific absorption rates (SARs) as the initial SAR.

4. The method of claim 2, comprising:
determining a scanning position of the target object; and
selecting the safety margin from a plurality of candidate safety margins based on the scanning position.

5. The method of claim 2, wherein the determining an initial SAR corresponding to the target RF shimming field parameter based on the target RF shimming field parameter and the target set includes:
determining a region to be scanned for the target object;
determining one or more target positions corresponding to the region to be scanned from the first count of target local hotspots; and
determining the initial SAR corresponding to the target RF shimming field parameter based on the target RF shimming field parameter and the one or more target positions.

6. The method of claim 1, further comprising:
determining object candidate positions of a simulation object and a candidate sensitivity distribution matrix corresponding to each object candidate position;
for each candidate RF shimming field parameter, determining the initial local hotspot corresponding to the candidate RF shimming field parameter based on the candidate sensitivity distribution matrix corresponding to each object candidate position and the candidate RF shimming field parameter.

7. The method of claim 1, wherein the determining an SAR estimated value for the target object based on a target RF shimming field parameter of an RF coil and the target set including:
retrieving, from a database, an RF coil port parameter matching the scanning information of the target object, the RF coil port parameter being related to a loss of RF signals by the RF coil;
obtaining an operating parameter of the RF coil; and
determining the SAR estimated value of the target object based on the operating parameter of the RF coil, the plurality of target sensitivity distribution matrices in the target set, and the RF coil port parameter.

8. The method of claim 7, wherein the determining the SAR estimated value of the target object based on the operating parameter of the RF coil, the plurality of target sensitivity distribution matrices in the target set, and the RF coil port parameter includes:
determining an absorption power ratio of the target object based on the plurality of target sensitivity distribution matrices in the target set and the RF coil port parameter;
determining a total absorption power of the MR device based on the operating parameter of the RF coil; and
determining the SAR estimated value of the target object based on the total absorption power of the MR device and the absorption power ratio of the target object.

9. The method of claim 8, wherein the determining an absorption power ratio of the target object based on the plurality of target sensitivity distribution matrices in the target set and the RF coil port parameter includes:
determining the absorption power ratio of the target object based on the plurality of target sensitivity distribution matrices in the target set, the RF coil port parameter, and the RF shimming field parameter.

10. The method of claim 8, wherein the database includes sensitivity distribution matrices for different body models, and an RF coil port parameter corresponding to each of the different body models.

11. The method of claim 10, wherein the RF coil port parameter corresponding to each of the different body models is related to a position of each RF channel relative to the corresponding body model.

12. The method of claim 8, wherein the SAR estimated value of the target object includes a whole-body SAR, the determining the SAR estimated value of the target object based on the total absorption power of the MR device and the absorption power ratio of the target object includes:
determining a product of the total absorption power of the MR device and the absorption power ratio of the target object; and
taking a ratio of the product to a mass of the target object as the whole-body SAR for the target object.

13. The method of claim 12, wherein the SAR estimated value of the target object further includes a local SAR, the determining the SAR estimated value of the target object based on the total absorption power of the MR device and the absorption power ratio of the target object includes:
obtaining a local sensitivity distribution matrix and a whole-body sensitivity distribution matrix of the target object; and
determining the local SAR of the target object based on the whole-body SAR of the target object, the local sensitivity distribution matrix and the whole-body sensitivity distribution matrix.

14. The method of claim 7, wherein the retrieving, from a database, an RF coil port parameter matching the scanning information of the target object includes:
obtaining image information of the target object; and
retrieving the RF coil port parameter from the database based on the image information and the scanning information of the target object.

15. A control method for magnetic resonance (MR) scanning, comprising:
obtaining a scanning sequence including a target radio frequency (RF) shimming field parameter, the target RF shimming field parameter being applied to a detection object through a plurality of transmission channels of a transmission coil;
determining a plurality of initial local hotspots of the detection object;
determining target local hotspots by clustering the plurality of initial local hotspots; and
determining a specific absorption rate (SAR) estimated value corresponding to the scanning sequence based on the target RF shimming field parameter and a target set, the target set including sensitivity distribution matrices corresponding to the target local hotspots.

16. The control method of claim 15, wherein the scanning sequence includes a first scanning sequence and a second scanning sequence performed sequentially, the first scanning sequence and the second scanning sequence are performed in a preset time range, and the target set includes a first set corresponding to the first scanning sequence and a second set corresponding to the second sequence; and
the determining an SAR estimated value corresponding to the scanning sequence based on the target RF shimming field parameter and a target set includes:
determining a third SAR based on the target RF shimming field parameter of the first scanning sequence and the first set;
determining a fourth SAR based on the target RF shimming field parameter of the second scanning sequence and the second set; and
determining the SAR estimated value corresponding to the scanning sequence by superposing the third SAR and the fourth SAR.

17. The control method of claim 15, wherein in a process of performing the scanning sequence, relative positions of the detection object and the transmission coil change, and the determining an SAR estimated value corresponding to the scanning sequence based on the target RF shimming field parameter and a target set includes:
before the relative positions change, determining a fifth SAR based on the target RF shimming field parameter and the target set;
after the relative positions change, determining a sixth SAR based on the target RF shimming field parameter and the target set; and
determining the SAR estimated value corresponding to the scanning sequence by superposing the fifth SAR and the sixth SAR.

18. A computer device, comprising:
at least one storage device including a set of instructions; and
at least one processor in communication with the at least one storage device, wherein when executing the set of instructions, the at least one processor is directed to perform operations including:
obtaining an initial radio frequency (RF) shimming field parameter;
by processing the initial RF shimming field parameter, obtaining object candidate positions in a simulation object and a candidate RF shimming field parameters corresponding to each object candidate position;
determining an initial local hotspot of a detection object corresponding to the each candidate RF shimming field parameter;
obtaining a plurality of target sensitivity distribution matrices corresponding to a plurality of target local hotspots based on a lookup table, the plurality of target local hotspots in the lookup table being obtained by clustering the plurality of initial local hotspots;
determining a safety allowance;
obtaining a target RF shimming field parameter;
determining an initial specific absorption rate (SAR) corresponding to the target RF shimming field parameter based on the target RF shimming field parameter and the target sensitivity distribution matrix corresponding to the each target local hotspot.

19. The computer device of claim 18, wherein the processor further performs the computer program by:
determining the each object candidate position in the simulation object and a candidate sensitivity distribution matrix corresponding to the each object candidate position;
determining the safety allowance based on the plurality of candidate sensitivity distribution matrices and the plurality of target sensitivity distribution matrices.

20. The computer device of claim 19, wherein the obtaining the plurality of target local hotspots by clustering the plurality of initial local hotspot includes:
obtaining the plurality of target local hotspots by clustering based on at least one of a position, a size and a feature value of each of the plurality of initial local hotspots.
